(19) United States
(12) Patent Application Publication
(10) Pub. No.: US 2013/0168790 A1
(43) Pub. Date: Jul. 4, 2013

(54) ORGANIC PHOTOELECTRIC CONVERSION ELEMENT AND IMAGE ELEMENT

(71) Applicant: FUJIFILM CORPORATION, Tokyo (JP)

(72) Inventor: Masayuki HAYASHI, Kanagawa (JP)

(73) Assignee: FUJIFILM CORPORATION, Tokyo (JP)

(21) Appl. No.: 13/774,262

(22) Filed: Feb. 22, 2013

Related U.S. Application Data
(62) Division of application No. 11/519,856, filed on Sep. 13, 2006.

(30) Foreign Application Priority Data
Sep. 20, 2005 (JP) 2005-272001

(51) Int. Cl. H01L 51/44

(52) U.S. Cl. CPC H01L 51/441
USPC 257/431

(57) ABSTRACT

An organic photoelectric conversion element comprises: a pair of electrodes; an organic photoelectric conversion layer arranged between the pair of electrodes; and an positive hole blocking layer arranged between one of the pair of electrodes and the organic photoelectric conversion layer, wherein an ionization potential of the positive hole blocking layer is larger than a work function of the adjoining electrode by 1.3 eV or more, and wherein an electron affinity of the positive hole blocking layer is equal to or larger than that of the adjoining organic photoelectric conversion layer. An electron blocking layer may be arranged between the other one of the pair of electrodes and the organic photoelectric conversion layer, wherein its electron affinity is smaller than a work function of the adjoining electrode by 1.3 eV or more, and its ionization potential is equal to or smaller than that of the adjoining organic photoelectric conversion layer.

This is a Divisional application of U.S. Ser. No. 11/519,856, filed Sep. 13, 2006, which claims priority under 35 U.S.C. §119 from Japanese Application 2005-272001, filed Sep. 20, 2005, the disclosures of which are incorporated herein by reference.

### BACKGROUND OF THE INVENTION

1. Field of the Invention

This invention relates to an organic photoelectric conversion element having an organic blocking layer. It also relates to an image element into which said organic photoelectric conversion element is integrated.

2. Description of the Related Art

In the case of organic thin film solar batteries, their non-bias performance is evaluated because their purpose is to take out electric power, but in the case of an image input element, an optical sensor and the like organic photoelectric conversion elements which require maximum induction of photoelectric conversion efficiency, it is frequent to apply voltage from outside for the purpose of improving photoelectric conversion efficiency and speed of response. In such a case, however, dark current is increased by positive hole injection or electron injection from an electrode caused by external electric field. There was a problem in that S/N ratio is reduced when dark current is increased exceeding the increase of photoelectric conversion efficiency caused by the external voltage.

JP-A-5-129576 claims that there are effects of S/N ratio improvement and speed of response improvement only in a blocking layer consisting of silicon oxide as the main component, arranged between an organic light receiving layer and an electrode in an organic photoelectric conversion element. However, since the silicon oxide as an insulating material is inserted into a depth of from 50 nm to 100 nm or more, not only positive hole blocking occurs but the carrier generated by the photoelectric conversion is also blocked, so that reduction of the efficiency is generated caused by the insertion of the blocking layer. In addition, sufficient S/N ratio improvement and speed of response improvement are not obtained by this method.

Also, in JP-T-2003-515933 (The term “JP-T” as used herein means a published Japanese translation of a PCT patent application.), an exciton inhibition layer consisting of an organic material is inserted between an electrode and an organic photoelectric conversion layer in an organic thin film solar battery system. In the designing guidance of the exciton inhibition layer, a material having an Eg (energy gap) value larger than the Eg of the organic photoelectric conversion material is used in the exciton inhibition layer.

On the other hand, JP-A-11-339966 and JP-A-2002-329582 propose organic materials as the positive hole blocking layer and electron blocking layer, but these are aimed at preventing passage of the carrier injected from an electrode without recombination, through a luminescent layer in the organic luminescent element.

### SUMMARY OF THE INVENTION

The object of the invention is to provide an organic photoelectric conversion element in which dark current is not increased and photoelectric conversion efficiency is not reduced even when voltage is applied from the outside for the purpose of improving photoelectric conversion efficiency and improving speed of response.

The organic blocking layer necessary for an organic photoelectric conversion element includes an organic positive hole blocking layer having a large positive hole injecting barrier from the anode and having a high transport capacity of electron as the photocurrent carrier, and an organic electron blocking layer having a large electron injecting barrier from the cathode and having a high movement capacity of positive hole as the photocurrent carrier. Like the case of the aforementioned JP-A-11-339966 and JP-A-2002-329582, a blocking layer which contains an organic material is already used in an organic luminescent element and the like in order to prevent passing of the carrier through the luminescent layer, and it was found that photoelectric conversion efficiency and speed of response can be improved by applying external voltage without reducing S/N ratio, by inserting such an organic blocking layer between an electrode and an organic film in an organic light receiving element.

Regarding the material to be used in the organic positive hole blocking layer, a material in which ionization potential (Ip) of the layer is larger than the work function (Wf) of the material of the adjoining electrode by a factor of 1.3 eV or more, and its electron affinity (Ea) is equal to or larger than the Ea of the material of the adjoining organic photoelectric conversion layer, is desirable. Regarding the material to be used in the organic electron blocking layer, a material in which Ea of the layer is smaller than the work function of the material of the adjoining electrode by a factor of 1.3 eV or more, and its Ip is equal to or larger than the Ip of the material of the adjoining organic photoelectric conversion layer, is desirable.

Further, a thickness of the organic positive hole blocking layer or the organic electron blocking layer is most preferably 10 nm to 200 nm. Since it is necessary to take out the carrier generated by photoelectric conversion, when the thickness is too thick, although the blocking ability is improved, the efficiency is lowered.

In addition, it is desirable that the voltage to be applied from the outside is from 1.0×10⁵ V/cm to 1.0×10⁷ V/cm based on the total thickness of the film (excluding the electrodes).

That is, the invention is based on the following means.

(1) An organic photoelectric conversion element comprising:

a pair of electrodes;

an organic photoelectric conversion layer arranged between the pair of electrodes; and

an organic positive hole blocking layer arranged between one of the pair of electrodes and the organic photoelectric conversion layer,

wherein an ionization potential of the organic positive hole blocking layer is larger than a work function of the adjoining one of the pair of electrodes by 1.3 eV or more, and

wherein an electron affinity of the organic positive hole blocking layer is equal to or larger than an electron affinity of the adjoining organic photoelectric conversion layer.

(2) An organic photoelectric conversion element comprising:

a pair of electrodes;

an organic photoelectric conversion layer arranged between the pair of electrodes; and

an organic electron blocking layer arranged between one of the pair of electrodes and the organic photoelectric conversion layer,

wherein an electron affinity of the organic electron blocking layer is smaller than a work function of the adjoining one of the pair of electrodes by 1.3 eV or more, and

wherein an ionization potential of the organic electron blocking layer is equal to or smaller than an ionization potential of the adjoining organic photoelectric conversion layer.

(3) An organic photoelectric conversion element comprising:

a pair of electrodes;

an organic photoelectric conversion layer arranged between the pair of electrodes;

an organic positive hole blocking layer arranged between one of the pair of electrodes and the organic photoelectric conversion layer; and

an organic electron blocking layer arranged between the other one of the pair of electrodes and the organic photoelectric conversion layer,

wherein an ionization potential of the organic positive hole blocking layer is larger than a work function of the adjoining one of the pair of electrodes by 1.3 eV or more, and

wherein an electron affinity of the organic positive hole blocking layer is equal to or larger than an electron affinity of the adjoining organic photoelectric conversion layer, and

wherein an electron affinity of the organic electron blocking layer is smaller than a work function of the adjoining other one of the pair of electrodes by 1.3 eV or more, and

wherein an ionization potential of the organic electron blocking layer is equal to or smaller than an ionization potential of the adjoining organic photoelectric conversion layer.

(4) The organic photoelectric conversion element as described in any of (1) to (3) above,

wherein an electron donative material is mixed in the organic positive hole blocking layer in an amount of from 0.1 wt % to 30 wt %.

(5) The organic photoelectric conversion element as described in (2) or (3) above,

wherein an electron acceptable material is mixed in the organic electron blocking layer in an amount of from 0.1 wt % to 30 wt %.

(6) The organic photoelectric conversion element as described in any of (1) to (5) above,

wherein a thickness of the organic blocking layer is from 10 nm to 200 nm.

(7) The organic photoelectric conversion element as described in any of (1) to (6) above,

wherein a voltage to be applied from an outside is from 1.0×10⁵ V/cm to 1.0×10⁷ V/cm.

(8) An image element comprising an organic photoelectric conversion element as described in any of (1) to (7) above.

### BRIEF DESCRIPTION OF THE INVENTION

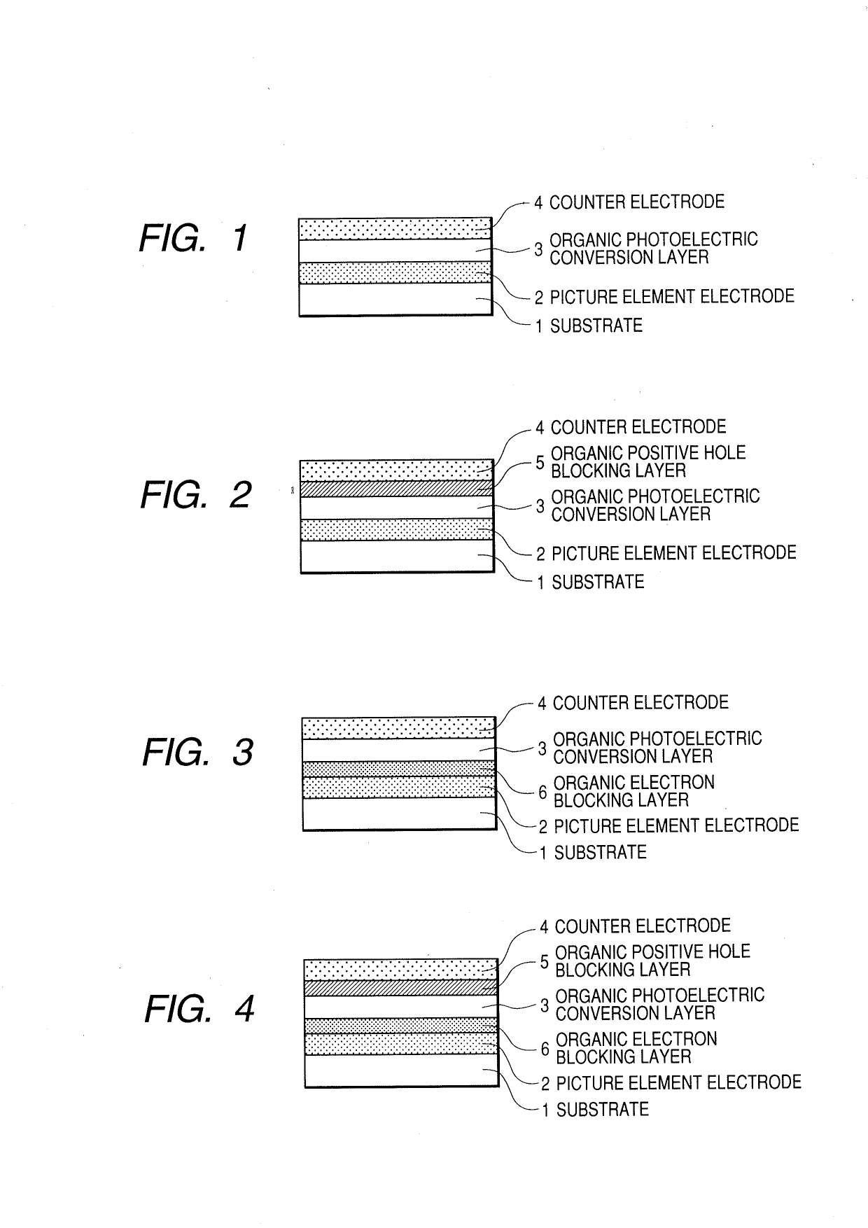

FIG. 1 is an illustration showing an organic photoelectric conversion element (no blocking layer) having an organic photoelectric conversion layer between a pair of electrodes;

FIG. 2 is an illustration showing an organic photoelectric conversion element of the invention having an organic photoelectric conversion layer and an organic positive hole blocking layer between a pair of electrodes;

FIG. 3 is an illustration showing an organic photoelectric conversion element of the invention having an organic photoelectric conversion layer and an organic electron blocking layer between a pair of electrodes;

FIG. 4 is an illustration showing an organic photoelectric conversion element of the invention having an organic positive hole blocking layer, an organic photoelectric conversion layer and an organic electron blocking layer between a pair of electrodes;

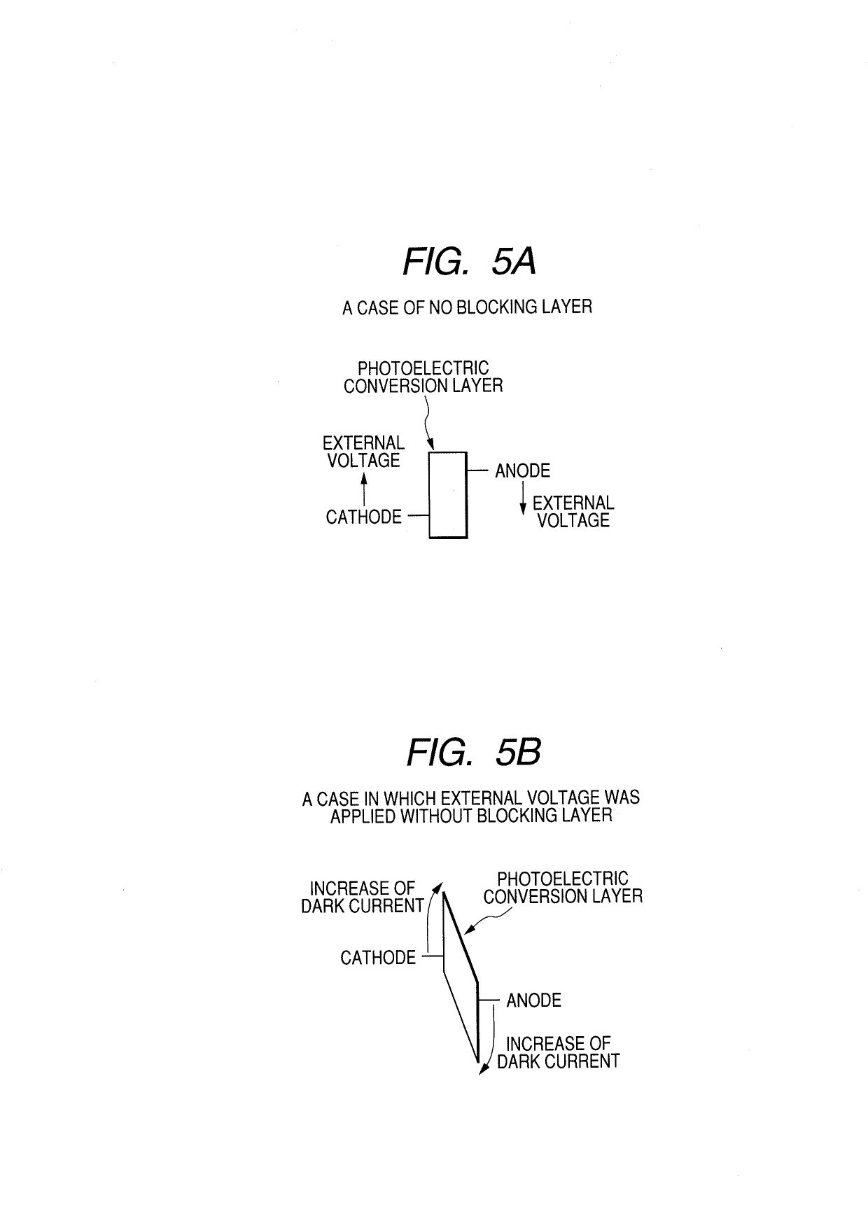

FIGS. 5A and 5B are illustrations showing energy flow of an organic photoelectric conversion element having no blocking layer;

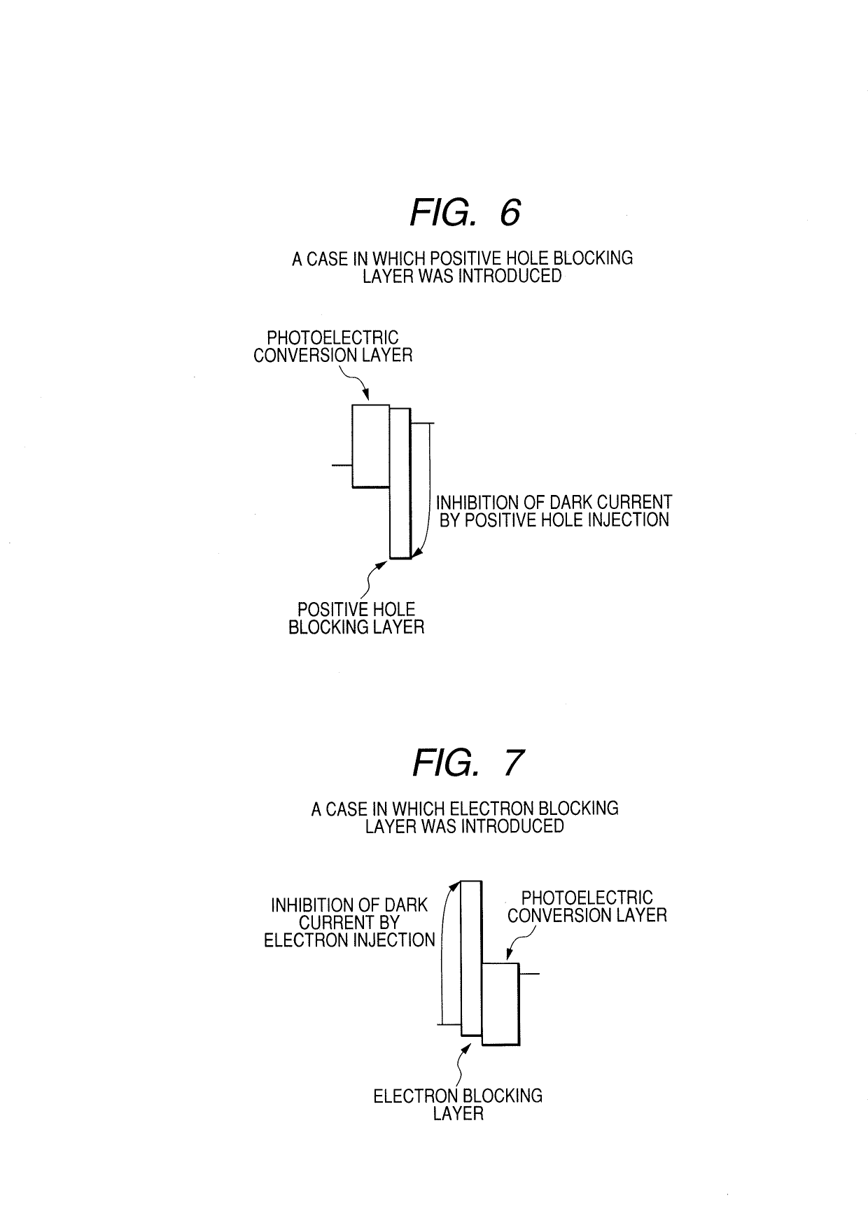

FIG. 6 is an illustration showing energy flow of an organic photoelectric conversion element having an organic positive hole blocking layer;

FIG. 7 is an illustration showing energy flow of an organic photoelectric conversion element having an organic electron blocking layer;

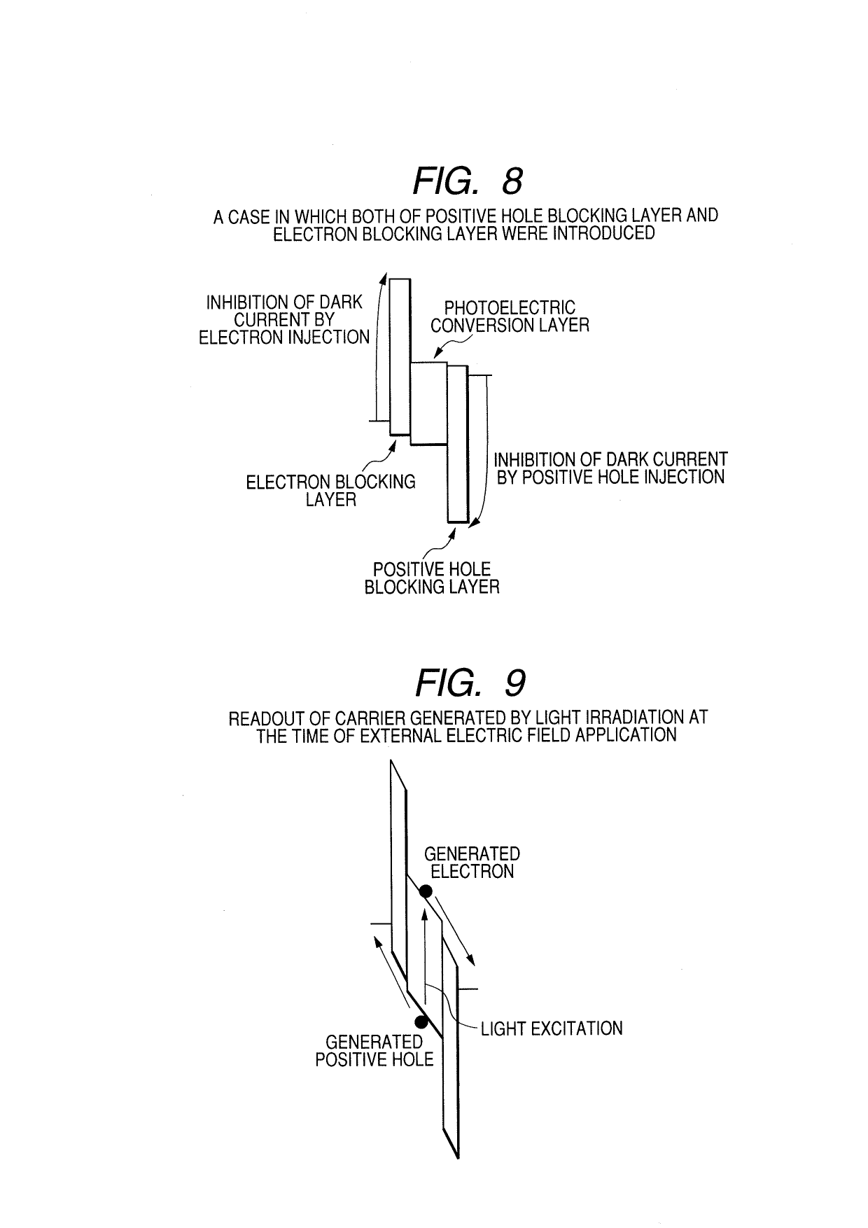

FIG. 8 is an illustration showing energy flow of an organic photoelectric conversion element having an organic positive hole blocking layer and an organic electron blocking layer;

FIG. 9 is an illustration showing light irradiation by external electric field application to an organic photoelectric conversion element having an organic positive hole blocking layer and an organic electron blocking layer;

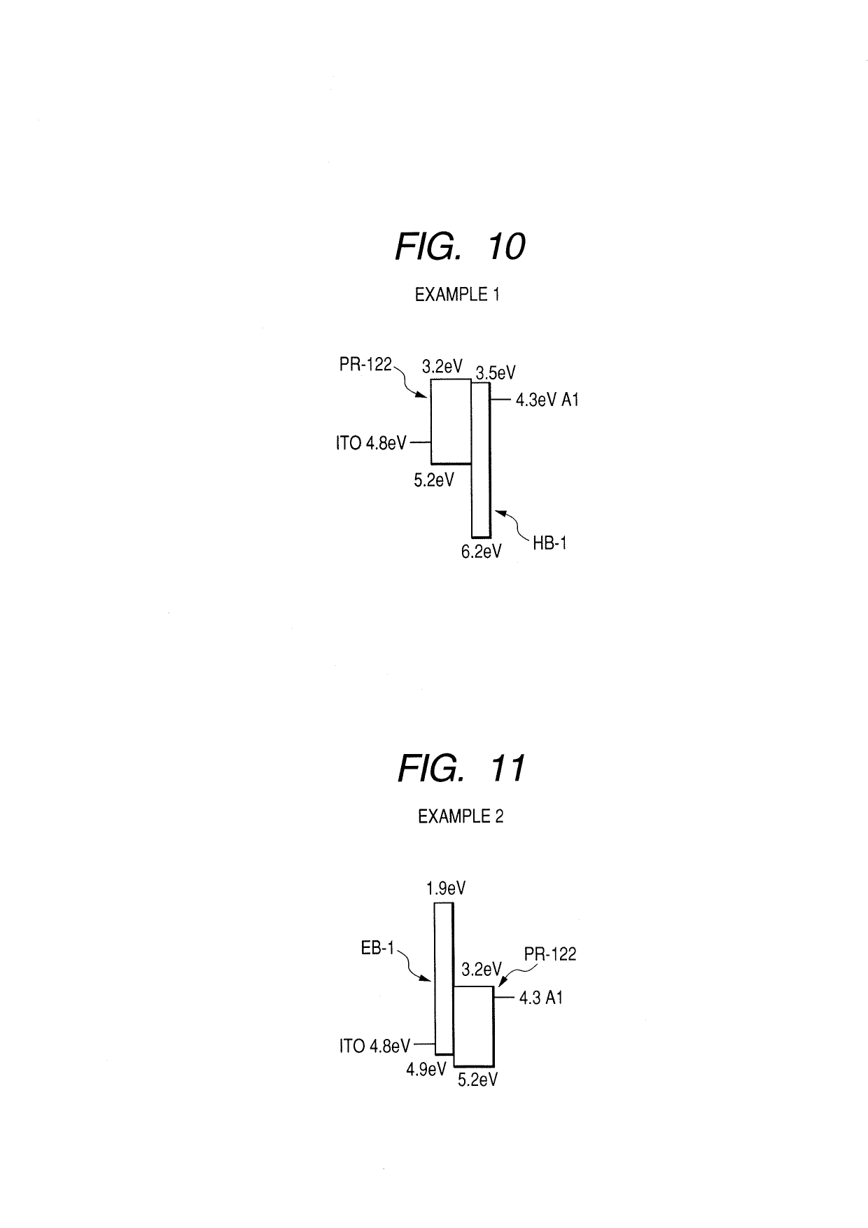

FIG. 10 is an explanatory drawing of Example 1;

FIG. 11 is an explanatory drawing of Example 2;

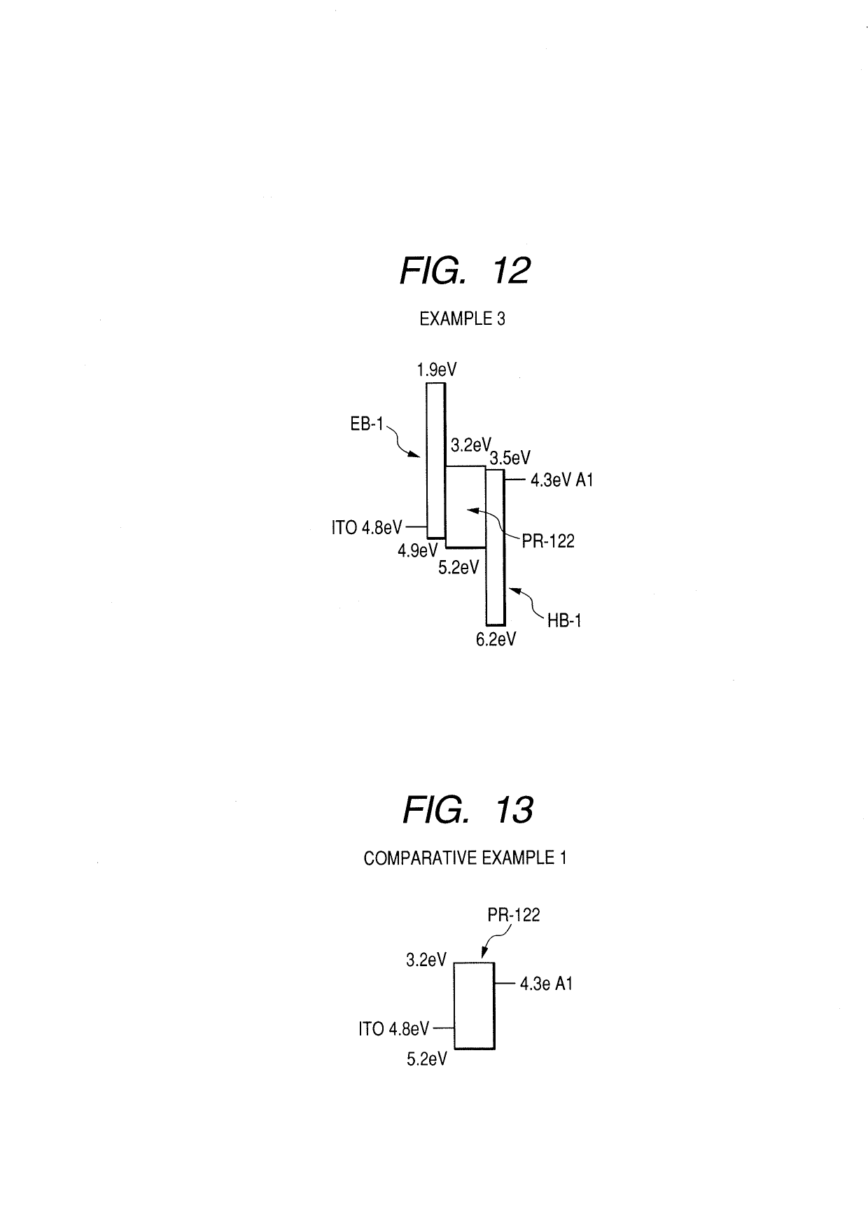

FIG. 12 is an explanatory drawing of Example 3;

FIG. 13 is an explanatory drawing of Comparative Example 1;

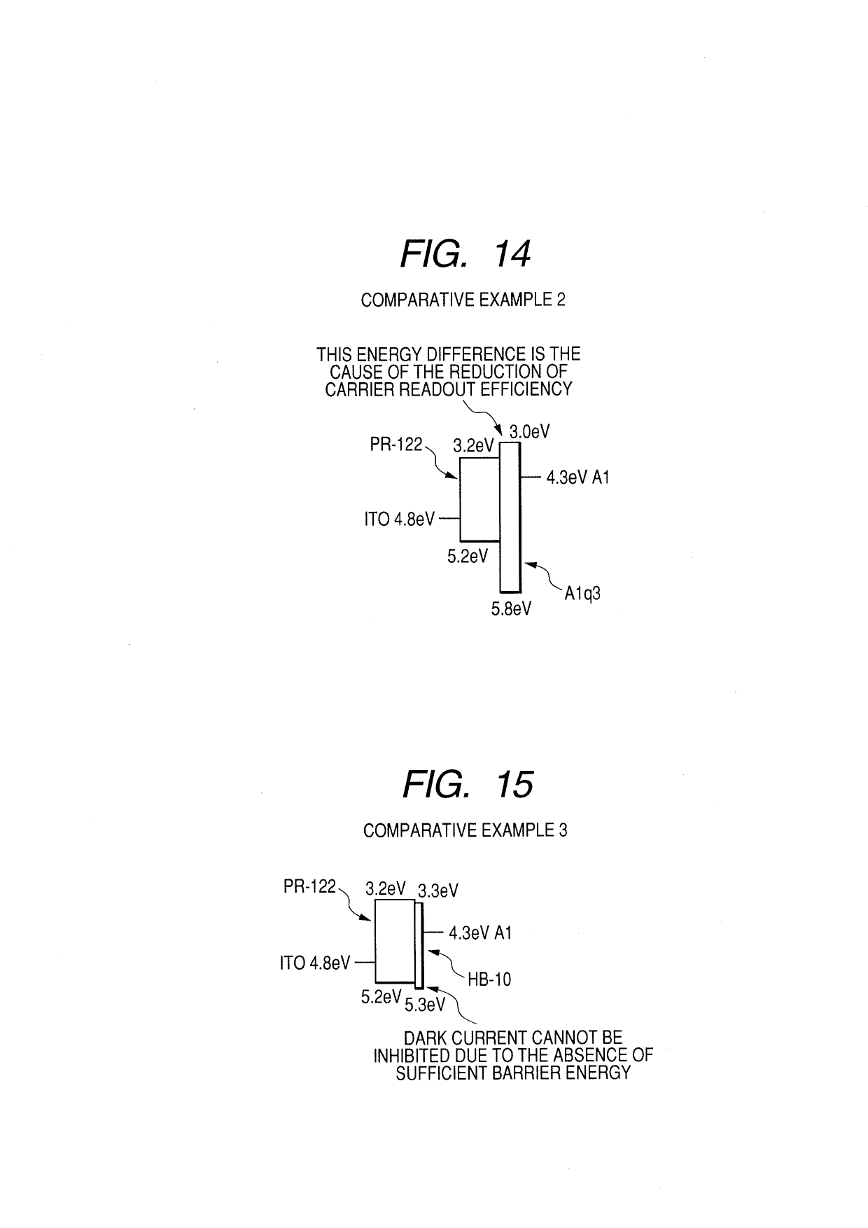

FIG. 14 is an explanatory drawing of Comparative Example 2;

FIG. 15 is an explanatory drawing of Comparative Example 3; and

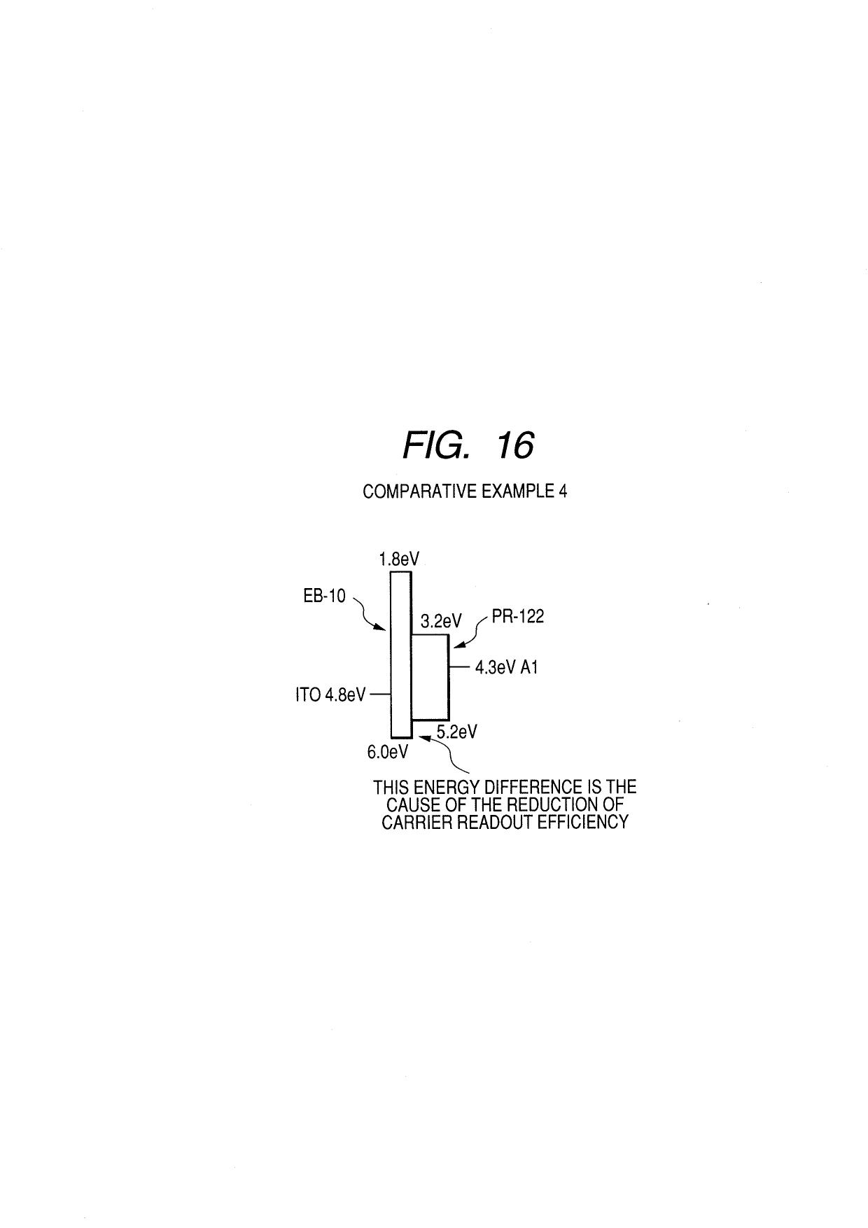

FIG. 16 is an explanatory drawing of Comparative Example 4.

### DETAILED DESCRIPTION OF THE INVENTION

An organic photoelectric conversion element has an organic photoelectric conversion layer between a pair of electrodes. For example, it has a picture element electrode 2, an organic photoelectric conversion layer 3 and a counter electrode 4 on a substrate 1 (FIG. 1).

In the case of the invention, the organic photoelectric conversion element has an organic blocking layer between an electrode and an organic photoelectric conversion layer. The organic blocking layer of the invention includes a positive hole blocking layer having a large positive hole injecting barrier from the anode and having a high transport capacity of electron as the photocurrent carrier, and an electron blocking layer having a large electron injecting barrier from the cathode and having a high movement capacity of positive hole as the photocurrent carrier.

When the organic photoelectric conversion element of the invention has a positive hole blocking layer, it has a positive hole blocking layer consisting of an organic compound between one of the electrodes and the organic photoelectric conversion layer. For example, it has a picture element electrode 2, an organic photoelectric conversion layer 3, an organic positive hole blocking layer 5 and a counter electrode 4 on a substrate 1 (FIG. 2).

When the organic photoelectric conversion element of the invention has an electron blocking layer, it has an electron blocking layer consisting of an organic compound between one of the electrodes and the organic photoelectric conversion layer. For example, it has a picture element electrode 2, an organic electron blocking layer 6, an organic photoelectric conversion layer 3 and a counter electrode 4 on a substrate 1 (FIG. 3).

When the organic photoelectric conversion element of the invention has a positive hole blocking layer and an electron blocking layer, it has a positive hole blocking layer consisting of an organic compound between one of the electrodes and the organic photoelectric conversion layer, and an electron blocking layer consisting of an organic compound between the other electrode and the organic photoelectric conversion layer. For example, it has a picture element electrode 2, an organic electron blocking layer 6, an organic photoelectric conversion layer 3, an organic positive hole blocking layer 5 and a counter electrode 4 on a substrate 1 (FIG. 4).

FIGS. 5A and 5B show an energy flow in an organic photoelectric conversion element which does not have a blocking layer like the case of FIG. 1. The energy flow when voltage is not applied (FIG. 5A) becomes FIG. 5B when voltage is applied, and dark current by the positive hole injection is increased in the anode, and dark current by the electron injection is increased in the cathode.

Contrary to this, when an organic positive hole blocking layer is arranged between the anode and the organic photoelectric conversion layer, it becomes the case of FIG. 6 and inhibits dark current by the positive hole injection in the anode. In this case, when ionization potential of the positive hole blocking layer is larger than the work function of the electrode which becomes the anode, by a factor of 1.3 eV or more, preferably 1.5 eV or more, more preferably 1.7 eV or more, and electron affinity of the positive hole blocking layer is equal to or larger than the electron affinity of the organic photoelectric conversion layer, dark current by the positive hole injection in the anode can be effectively inhibited, and the readout efficiency of carrier is not lowered.

Also, when an organic electron blocking layer is arranged between the cathode and the organic photoelectric conversion layer, it becomes the case of FIG. 7 and inhibits dark current by the electron injection in the cathode. In this case, when electron affinity of the electron blocking layer is smaller than the work function of the electrode which becomes the cathode by a factor of 1.3 eV or more, and ionization potential of the electron blocking layer is equal to or smaller than the electron affinity of the organic photoelectric conversion layer, dark current by the electron injection in the cathode can be effectively inhibited, and the readout efficiency of carrier is not lowered.

In addition, when an organic positive hole blocking layer is arranged between the anode and the organic photoelectric conversion layer, and an organic electron blocking layer is arranged between the cathode and the organic photoelectric conversion layer, it becomes the case of FIG. 8, and inhibits dark current by the positive hole injection in the anode and also inhibits dark current by the electron injection in the cathode. In this case, when ionization potential of the positive hole blocking layer is larger than the work function of the electrode which becomes the anode by a factor of 1.3 eV or more, and electron affinity of the positive hole blocking layer is equal to or larger than the electron affinity of the organic photoelectric conversion layer, dark current by the positive hole injection in the anode can be effectively inhibited, and the readout efficiency of carrier is not lowered, and when electron affinity of the electron blocking layer is smaller than the work function of the electrode which becomes the cathode, by a factor of 1.3 eV or more, preferably 1.5 eV or more, more preferably 1.7 eV or more, and ionization potential of the electron blocking layer is equal to or smaller than the electron affinity of the organic photoelectric conversion layer, dark current by the electron injection in the cathode can be effectively inhibited, and the readout efficiency of carrier is not lowered.

In the case of the organic photoelectric conversion element of the invention, when an organic positive hole blocking layer and an organic electron blocking layer are together arranged between both electrodes and the organic photoelectric conversion layer and subjected to light irradiation by applying voltage, it becomes the case of FIG. 9, and the electron generated by the light irradiation is smoothly transferred toward the anode, and the positive hole toward the cathode.

### [Organic Positive Hole Blocking Layer]

An electron acceptable organic material can be used in the positive hole blocking layer.

As the electron acceptable organic material, fullerene and carbon nanotube including C60 and C70 and derivatives thereof, 1,3-bis(4-tert-butylphenyl-1,3,4-oxadiazolyl)phenylene (OXD-7) or the like oxadiazole derivative, an anthraquinone-dimethane derivative, a diphenylquinone derivative, Bathocuproine and Basophenanthroline and derivatives thereof, a triazole compound, a tris(8-hydroxyquinolinate) aluminum complex, a bis(4-methyl-8-quinolinate) aluminum complex, a distyrylarylene derivative, a Silole compound and the like can be used.

Thickness of the positive hole blocking layer is 10 nm or more and 200 nm or less, more preferably 30 nm or more and 150 nm or less, particularly preferably 50 nm or more and 100 nm or less.

As a candidate of the positive hole blocking material, the following materials can be illustratively exemplified.

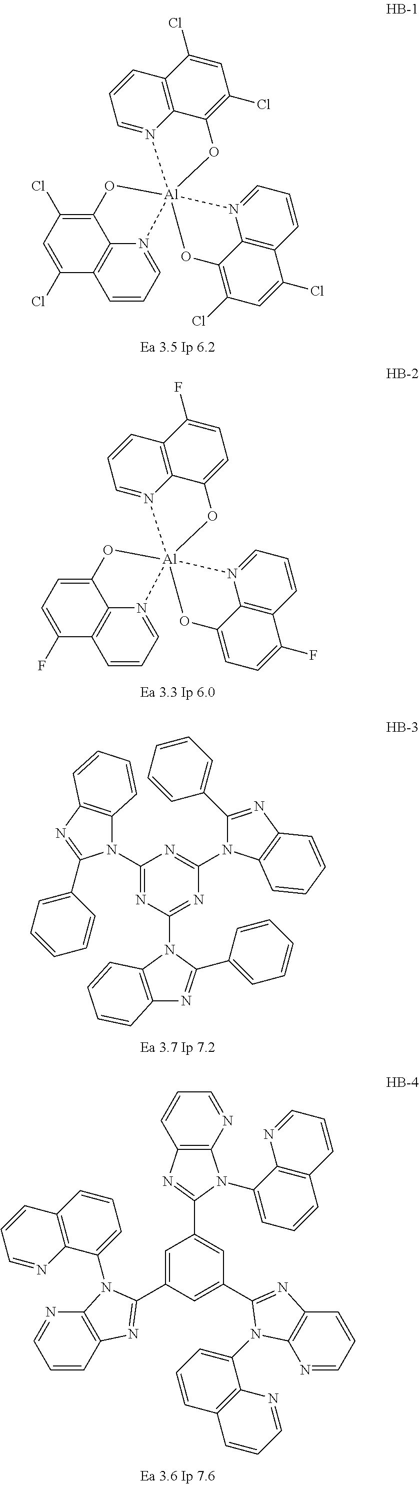

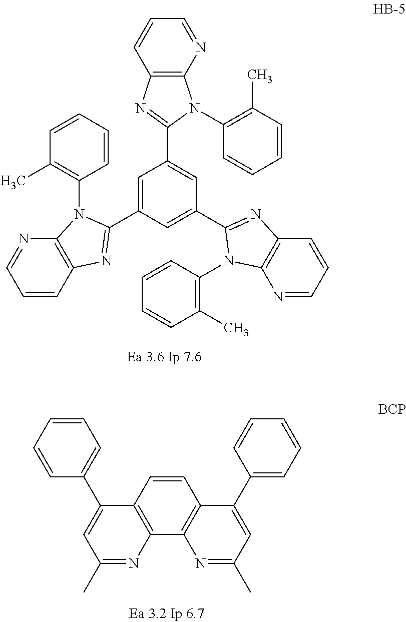 [SMILES: Cc1ccccc1-n1c(-c2cc(-c3nc4cccnc4n3-c3ccccc3C)cc(-c3nc4cccnc4n3-c3ccccc3C)c2)nc2cccnc21 ; Cc1cc(-c2ccccc2)c2ccc3c(-c4ccccc4)cc(C)nc3c2n1]

Regarding the material actually used in the positive hole blocking layer, the range of selection is restricted depending on the material of the adjoining electrode and the material of the organic photoelectric conversion layer. Preferred is a material in which its ionization potential (Ip) is larger than the work function (Wf) of the material of the adjoining electrode by a factor of 1.3 eV or more, and its electron affinity (Ea) is an equivalent Ea to or a larger Ea than that of the material of the adjoining organic photoelectric conversion layer.

In this connection, it is possible to further reduce the dark current by mixing an electron donative material in an amount of from 0.1 wt % to 30 wt %, preferably from 0.3 wt % to 20 wt %, more preferably from 0.5 wt % to 10 wt %, in the positive hole blocking layer.

As the candidate of such an electron donative material to be doped in the positive hole blocking layer, the following materials can for example be cited.

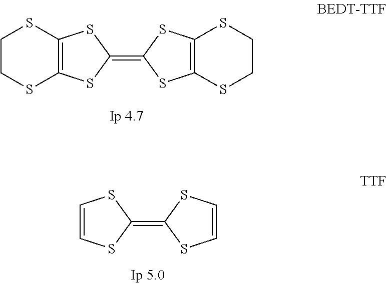 [SMILES: C1CSC2=C(S1)SC(=C1SC3=C(SCCS3)S1)S2 ; C1=CSC(=C2SC=CS2)S1]

### [Organic Electron Blocking Layer]

An electron donative organic material can be used in the electron blocking layer.

Illustratively, as low molecular materials, N,N′-bis(3-methylphenyl)-(1,1′-biphenyl)-4,4′-diamine (TPD), 4,4′-bis[N-(naphthyl)-N-phenyl-amino]biphenyl (α-NPD) and the like aromatic diamine compounds, oxazole, oxadiazole, triazole, imidazole, imidazolone, a stilbene derivative, a pyrazolone derivative, tetrahydroimidazole, polyarylalkane, butadiene, 4,4′-4″-tris(N-(3-methylphenyl)N-phenylamino)triphenylamine (m-MTDATA), porphine, tetraphenylporphine cupper, phthalocyanine, cupper phthalocyanine, titanium phthalocyanine oxide and the like porphine compounds, a triazole derivative, an oxadiazole derivative, an imidazole derivative, a polyarylalkane derivative, a pyrazolone derivative, a pyrazolone derivative, a phenylenediamine derivative, an amylamine derivative, an amino-substituted chalcone derivative, an oxazole derivative, a styrylanthracene derivative, a fluorenone derivative, a hydrazone derivative, a silazane derivative and the like can be used, and as high molecular materials, phenylenevinylene, fluorene, carbazole, indole, pyrene, pyrrole, picoline, thiophene, acetylene, diacetylene and the like polymers and derivatives thereof can be used.

Film thickness of the electron blocking layer is preferably 10 nm or more and 200 nm or less, more preferably 30 nm or more and 150 nm or less, and particularly preferably 50 nm or more and 100 nm or less.

In addition, as the candidate of the electron blocking material, the following materials can be illustratively exemplified.

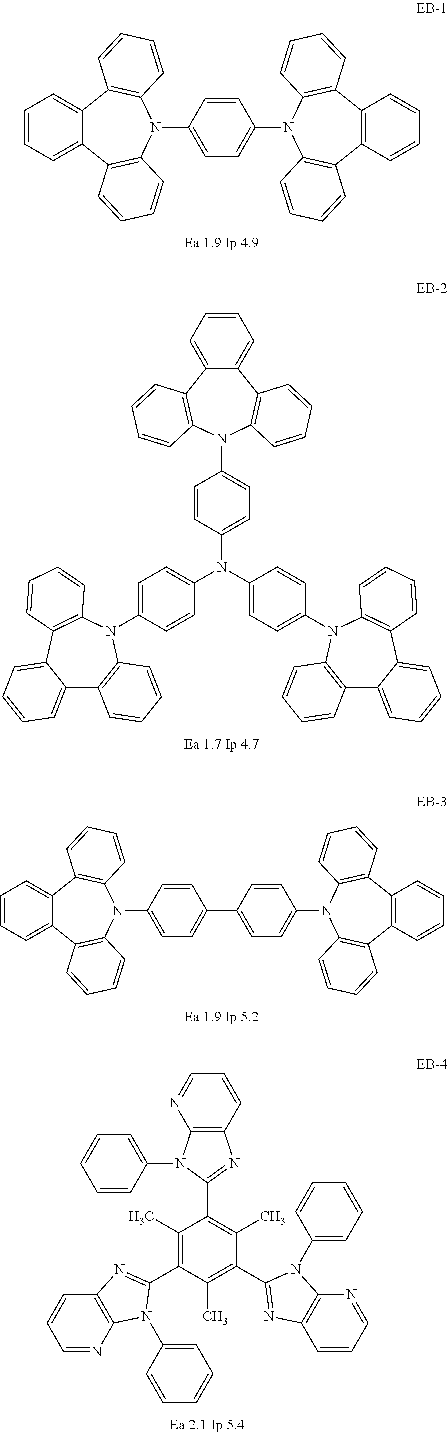 [SMILES: c1ccc2c(c1)-c1ccccc1N(c1ccc(N3c4ccccc4-c4ccccc4-c4ccccc43)cc1)c1ccccc1-2 ; c1ccc2c(c1)-c1ccccc1N(c1ccc(N(c3ccc(N4c5ccccc5-c5ccccc5-c5ccccc54)cc3)c3ccc(N4c5ccccc5-c5ccccc5-c5ccccc54)cc3)cc1)c1ccccc1-2 ; c1ccc2c(c1)-c1ccccc1N(c1ccc(-c3ccc(N4c5ccccc5-c5ccccc5-c5ccccc54)cc3)cc1)c1ccccc1-2 ; Cc1c(-c2nc3cccnc3n2-c2ccccc2)c(C)c(-c2nc3cccnc3n2-c2ccccc2)c(C)c1-c1nc2cccnc2n1-c1ccccc1]

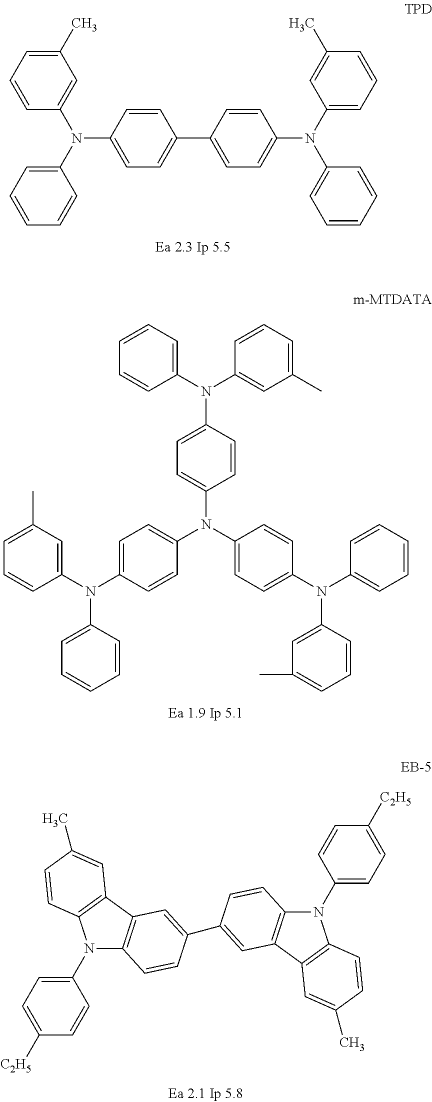 [SMILES: Cc1cccc(N(c2ccccc2)c2ccc(-c3ccc(N(c4ccccc4)c4cccc(C)c4)cc3)cc2)c1 ; Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1 ; CCc1ccc(-n2c3ccc(C)cc3c3cc(-c4ccc5c(c4)c4cc(C)ccc4n5-c4ccc(CC)cc4)ccc32)cc1]

Regarding the material actually used in the electron blocking layer, the range of selection is restricted depending on the material of the adjoining electrode and the material of the organic photoelectric conversion layer. Preferred is a material in which its electron affinity (Ea) is larger than the work function (Wf) of the material of the adjoining electrode by a factor of 1.3 eV or more, and its ionization potential (Ip) is an equivalent Ip to or a smaller Ip than that of the material of the adjoining organic photoelectric conversion layer.

In this connection, it is possible to further reduce the dark current by mixing an electron acceptable material in an amount of from 0.1 wt % to 30 wt %, preferably from 0.3 wt % to 20 wt %, more preferably from 0.5 wt % to 10 wt %, in the electron blocking layer.

As the candidate of such an electron acceptable material to be doped in the electron blocking layer, the following materials can for example be cited.

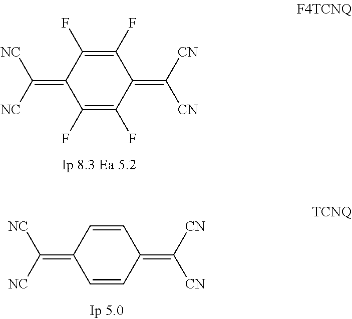 [SMILES: N#CC(C#N)=c1c(F)c(F)c(=C(C#N)C#N)c(F)c1F ; N#CC(C#N)=c1ccc(=C(C#N)C#N)cc1]

The ionization potential (Ip) of organic materials was measured using a surface analyzer AC-1 manufactured by RIKEN KEIKI. Illustratively, each organic material was formed into a film of about 100 nm in thickness on a substrate and measured with a quality of light of from 20 to 50 nW and an analytical area of 4 mmφ.

A compound having large ionization potential was measured using UPS (ultraviolet photoelectron spectrophotometry).

In calculating the electron affinity (Ea), spectrum of each organic material made into a film was firstly measured, and its energy at the absorption end was calculated. Thereafter, the electron affinity value was obtained by subtracting this energy at the absorption end from the ionization potential value.

### [Substrate]

According to the organic photoelectric conversion element of the invention, it is not particularly necessary that light can permeate through the substrate, but a substrate showing high heat stability in the process and having a moisture and oxygen permeability as small as possible is desirable. When flexibility is not necessary, it may be zirconia stabilized yttrium (YSZ), glass or the like inorganic material, or a metal plate such as of zinc, aluminum, stainless steel, chromium, tin, nickel, iron, nickel copper or the like or a ceramic plate. When flexibility is necessary, polyethylene terephthalate, polybutylene phthalate, polyethylene naphthalate and the like polyesters and polystyrene, polycarbonate, polyether sulfone, polyacrylate, polyimide, polycycloolefin, norbornane resin, poly(chlorotrifluoroethylene) and the like organic materials can be exemplified. In addition, it may be an opaque plastic substrate. Among the aforementioned materials, polycarbonate or the like is suitably used from the heat resistance and the like point of view. In the case of an organic material, it is desirable to have excellent dimensional stability, solvent resistance, electric insulation and workability, in addition to the heat resistance. When a flexible substrate as described in the above is used, its lightening can be effected in comparison with the use of glass, a metal or a ceramic substrate, its portability can be improved, and it can be made into a product having strong bending stress. It is appropriate that thickness of the plastic substrate is from 20 μm to 500 μm.

### [Picture Element Electrode and Counter Electrode]

According to the organic photoelectric conversion element of the invention, the picture element electrode may be used either as the anode or as a cathode. When used as the anode, it takes out electrons from the adjoining photoelectric conversion layer or positive hole blocking layer, and when used as the cathode, it takes out positive holes from the adjoining photoelectric conversion layer or electron blocking layer.

An electrode which becomes a counter electrode of the picture element electrode of each of the light receiving part and light generation part is arranged on the counter electrode. It is necessary that the counter electrode is transparent or semitransparent for the purpose of improving the efficiency for light utilization, and it is desirable that this electrode has a light transmittance of at least 50% or more, preferably 70% or more, more preferably 90% or more, in the visible light wavelength region of from 400 nm to 700 nm.

Materials of the picture element electrode and counter electrode are materials which can use a metal, an alloy, a metal oxide, an electro-conductive compound, a mixture thereof and the like, and are selected by taking adhesiveness and electron affinity with the adjoining layer, ionization potential, stability and the like into consideration.

As their illustrative examples, tin oxide, zinc oxide, indium oxide, indium tin oxide (ITO) and the like conductive metal oxides, gold, silver, corium, nickel and the like metals, mixtures or laminates of these metals with conductive metal oxides, copper iodide, copper sulfate and the like inorganic conductive substances, polyaniline, polythiophene, polypyrrole and the like organic conductive materials, silicon compounds and their laminates with ITO and the like can be exemplified as the material of the anode, of which conductive metal oxides are desirable, and ITO and IZO are particularly desirable from the productivity, high conductivity, transparency and the like points of view.

As the material of the cathode, alkali metals (e.g., Li. Na, K and the like) and fluorides or oxides thereof, alkaline earth metals (e.g., Mg, Ca and the like) and fluorides or oxides thereof, gold, silver, lead, aluminum, sodium-potassium alloys or mixed metals thereof, lithium-aluminum alloys or mixed metals thereof, magnesium-silver alloys or mixed metals thereof, indium, ytterbium and the like rare earth metals and the like can be exemplified, of which those materials having a work function of 4 eV or less are desirable, and aluminum, silver, gold or a mixed metal thereof and the like are more desirable. The cathode can take not only a single layer structure of the aforementioned compounds and mixtures but also a laminate structure containing the aforementioned compounds and mixtures. For example, a laminate structure of aluminum/lithium fluoride or aluminum/lithium oxide can be cited. Also, it is possible to deposit two components or more at the same time. In addition, it is also possible to form an alloy electrode by simultaneously depositing two or more metals, or an alloy prepared in advance may be deposited.

Film thickness of the picture element electrode can be optionally selected depending on the material, but is generally within the range of preferably 10 nm or more and 1 μm or less, more preferably 30 nm or more and 500 nm or less, further preferably 50 nm or more and 300 nm or less.

Film thickness of the counter electrode can be optionally selected depending on the material, but may be as thin as possible for the purpose of increasing light transmittance, and is generally within the range of preferably 3 nm or more and 500 nm or less, more preferably 5 nm or more and 300 nm or less, further preferably 7 nm or more and 100 nm or less.

It is desirable that sheet resistance the anode and cathode is low, and several hundred Ω/□ or less is desirable.

Regarding the method for forming an electrode, a dry film forming method or a wet film forming method can be used. As illustrative examples of the dry film forming method, a vacuum deposition method, a spattering method, an ion plating method, an MBE method or the like physical vapor phase epitaxy method or a plasma polymerization or the like CVD method can be cited. As the wet film forming method, a cast method, a spin coat method, a dipping method, an LB method or the like coating method can be used. In addition, an ink jet printing, screen printing or the like printing method or a thermal transfer, laser transfer or the like transferring method may also be used. Patterning may be carried out by a chemical etching by photolithography or the like means, by a physical etching by an ultraviolet ray, laser or the like means, by a vacuum deposition, spattering or the like means after overlaying a mask, or by a lift off method, a printing method or a transferring method.

In forming the counter electrode, it is necessary to take a precaution for not causing damage upon the organic film lying right beneath it. For example, when a film of ITO or the like transparent electrode is formed, it is desirable to prepare it under a plasma-free condition. By preparing a transparent electrode film under a plasma-free condition, influence of plasma upon the substrate can be lessened, and photoelectric conversion characteristics can be improved. In this connection, the plasma-free means that plasma is not generated in the transparent electrode film during film formation, or a condition in which the space between the plasma generation source and the substrate has a distance of 2 cm or more, preferably 10 cm or more, more preferably 20 cm or more, so that the plasma reaching the substrate is reduced.

Examples of the device for not generating plasma in the transparent electrode during film formation include an electron beam deposition device (EB deposition device) and a pulse laser deposition device. Regarding the EB deposition device or a pulse laser deposition device, the devices described in “New Development of Transparent Conductive Film (written in Japanese)” edited by Y. Sawada (published by CMC, 1999), “New Development of Transparent Conductive Film II (written in Japanese)” edited by Y. Sawada (published by CMC, 2002), or “Techniques of Transparent Conductive Film (written in Japanese)” edited by Japan Science Foundation (published by Ohm, 1999), or in the references appended therein can be used. Regarding the device which can realize a condition in which the space between the plasma generation source and the substrate has a distance of 2 cm or more so that the plasma reaching the substrate is reduced (to be referred to as plasma-free film forming device hereinafter), a counter target type spatter device, an arc plasma deposition method and the like can for example be considered, and the devices described in “New Development of Transparent Conductive Film (written in Japanese)” edited by Y. Sawada (published by CMC, 1999), “New Development of Transparent Conductive Film II (written in Japanese)” edited by Y. Sawada (published by CMC, 2002), or “Techniques of Transparent Conductive Film (written in Japanese)” edited by Japan Science Foundation (published by Ohm, 1999), or in the references appended therein can be used.

### [Organic Layer]

The organic layer is arranged by interposing between the picture element electrode and counter electrode, and its construction may be the photoelectric conversion layer alone, a laminate of an electron blocking layer, a positive hole transporting layer, an electron transporting layer, a positive hole blocking layer, a crystallization preventing layer, a buffer layer, a smoothing layer and the like, or a mixture of these layers. As illustrative constructions of the light receiving layer (includes electrodes), cathode/electron blocking layer/photoelectric conversion layer/positive hole blocking layer/anode, cathode/electron blocking layer/positive hole transporting layer/photoelectric conversion layer/electron transporting layer/positive hole blocking layer/anode, cathode/electron blocking layer/photoelectric conversion layer/positive hole blocking layer/buffer layer/anode, cathode/electron blocking layer/crystallization preventing layer/photoelectric conversion layer/positive hole blocking layer/anode and the like can be exemplified. In addition, two or more of photoelectric conversion'layers, electron blocking layers, positive hole transporting layers, electron transporting layers, positive hole blocking layers, crystallization preventing layers, buffer layers, smoothing layers and the like may be arranged.

Though it depends on the construction of the whole device, it is desirable that the photoelectric conversion layer absorbs all of blue light, green light and red light and carries out their photoelectric conversion, absorbs two of these lights and carries out their photoelectric conversion, or absorbs only one of them and carries out its photoelectric conversion. The blue light absorption layer can absorb a light of at least from 400 to 500 nm, and absorption ratio of the peak wave length within the wavelength range is preferably 50% or more. The green light absorption layer can absorb a light of at least from 500 to 600 nm, and absorption ratio of the peak wave length within the wavelength range is preferably 50% or more. The red light absorption layer can absorb a light of at least from 600 to 700 nm, and absorption ratio of the peak wave length within the wavelength range is preferably 50% or more.

Regarding the photoelectric conversion layer, an n-type semiconductor or a p-type semiconductor can be used as a single layer, but it is desirable to use an n-type semiconductor and a p-type semiconductor in combination.

The organic p-type semiconductor is a donor type organic semiconductor and means an organic compound mainly typified by a positive hole transportable organic compound having a property to easily provide electron. More illustratively, it means an organic compound which shows smaller ionization potential when two organic materials are used by allowing to contact with each other. Accordingly, any organic compound can be used as the donor type organic compound, with the proviso that it is an organic compound having a property to donate electron. For example, a triarylamine compound, a benzidine compound, a pyrazoline compound, a styrylamine compound, a hydrazone compound, a triphenylmethane compound, a carbazole compound, a polysilane compound, a thiophene compound, a phthalocyanine compound, a cyanine compound, a merocyanine compound, an oxonole compound, a polyamine compound, an indole compound, a pyrrole compound, a pyrazole compound, a polyallylene compound, a condensed aromatic carbocyclic compound (a naphthalene derivative, an anthracene derivative, a phenanthrene derivative, a tethracene derivative, a pyrene derivative, a perylene derivative or a fluoranthene derivative), a metal complex having a nitrogen-containing heterocyclic compound as the ligand and the like can be used. In this connection, not only these compounds but other compound may also be used as the donor type organic semiconductor, with the proviso that it is an organic compound which, as described in the foregoing, has smaller ionization potential than that of the organic compound used as the n-type (acceptor type) compound.

The organic n-type semiconductor is an acceptor type organic semiconductor and means an organic compound mainly typified by an electron transportable organic compound having a property to easily receive electron. More illustratively, it means an organic compound which shows larger electron affinity when two organic compounds are used by allowing to contact with each other. Accordingly, any organic compound can be used as the acceptor type organic compound, with the proviso that it is an organic compound having a property to accept electron. For example, a condensed aromatic carbocyclic compound (a naphthalene derivative, an anthracene derivative, a phenanthrene derivative, a tethracene derivative, a pyrene derivative, a perylene derivative or a fluoranthene derivative), a 5- to 7-membered heterocyclic compound containing hydrogen atom, oxygen atom or sulfur atom (e.g., pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyrazolidine, pyrrolopyridine, thiadiazolopyridine, dibenzazepine, tribenzazepine or the like), a polyallylene compound, a fluorene compound, a cyclopentadiene compound, a silyl compound, a metal complex having a nitrogen-containing heterocyclic compound as the ligand and the like can be cited. In this connection, not only these compounds but other compound may also be used as the acceptor type organic semiconductor, with the proviso that it is an organic compound which, as described in the foregoing, has larger electron affinity than that of the organic compound used as the donor type organic compound.

In addition, a p-type organic pigment and an n-type organic pigment can also be used as the p-type organic semiconductor and n-type organic semiconductor, with their preferred examples including a cyanine pigment, a styryl pigment, a hemicyanine pigment, a merocyanine pigment (including zero-methine merocyanine (simple merocyanine)), a tri-nuclear merocyanine pigment, a tetra-nuclear merocyanine pigment, a rhodacyanine pigment, a complex cyanine pigment, a complex merocyanine pigment, an allopolar pigment, an oxonole pigment, a hemi-oxonole pigment, a squalium pigment, a croconium pigment, an azamethine pigment, a coumarin pigment, an allylidene pigment, an anthraquinone pigment, a triphenylmethane pigment, an azo pigment, an azomethine pigment, a spiro compound, a metallocene pigment, a fluorenone pigment, a fulgide pigment, a perylene pigment, a phenazine pigment, a phenothiazine pigment, a quinone pigment, an indigo pigment, a diphenylmethane pigment, a polyene pigment, an acridine pigment, an acridinone pigment, a diphenylamine pigment, a quinacridone pigment, a quinophthalone pigment, a phenoxazine pigment, a phthaloperylene pigment, a porphyrin pigment, a chlorophyll pigment, a phthalocyanine pigment, a metal complex pigment and a condensed aromatic carbocyclic compound (a naphthalene derivative, an anthracene derivative, a phenanthrene derivative, a tethracene derivative, a pyrene derivative, a perylene derivative or a fluoranthene derivative).

Next, the metal complex compound is described. The metal complex compound is a metal complex having a ligand containing at least one nitrogen atom, oxygen atom or sulfur atom which coordinates with a metal, and the metal ion in the metal complex is not particularly limited but is preferably beryllium ion, magnesium ion, aluminum ion, gallium ion, zinc ion, indium ion or tin ion, more preferably beryllium ion, aluminum ion, gallium ion or zinc ion, further preferably aluminum ion or zinc ion. Regarding the ligand to be contained in the aforementioned metal complex, there are various conventionally known ligands, and their examples include those ligands which are described for example in “Photochemistry and Photophysics of Coordination Compounds” published in 1987 by Springer-Verlag and “Organic Metal Chemistry—Foundation and Application—” (written in Japanese) published in 1987 by Shokabo.

Preferred as the aforementioned ligand is a nitrogen-containing heterocyclic ligand (preferably having from 1 to 30, more preferably from 2 to 20, particularly preferably from 3 to 15 carbon atoms) which may be monodentate ligand or a ligand of di- or more dentate. Preferred is a didentate. For example, a pyridine ligand, a bipyridyl ligand, a quinolyl ligand, a hydroxyphenylazole ligand (hydroxyphenylbenzimidazole, hydroxyphenylbenzoxazole ligand or hydroxyphenylimidazole ligand), an alkoxy ligand (having preferably from 1 to 30, more preferably from 1 to 20, particularly preferably from 1 to 10 carbon atoms, such as methoxy, ethoxy, 2-ethylhexyloxy or the like), an aryloxy ligand (having preferably from 6 to 30, more preferably from 6 to 20, particularly preferably from 6 to 12 carbon atoms, such as phenyloxy, 1-naphthyloxy, 2-naphthyloxy, 2,4,6-trimethylphenyloxy, 4-biphenyloxy or the like), a heteroaryloxy ligand (having preferably from 1 to 30, more preferably from 1 to 20, particularly preferably from 1 to 12 carbon atoms, such as pyridyloxy, pyrazyloxy, pyrimidyloxy, quinolyloxy or the like), an alkylthio ligand (having preferably from 1 to 30, more preferably from 1 to 20, particularly preferably from 1 to 12 carbon atoms, such as methylthio, ethylthio or the like), an arylthio ligand (having preferably from 6 to 30, more preferably from 6 to 20, particularly preferably from 6 to 12 carbon atoms, such as phenylthio or the like), a heterocyclic substituted thio ligand (having preferably from 1 to 30, more preferably from 1 to 20, particularly preferably from 1 to 12 carbon atoms, such as pyridylthio, 2-benzimidazolylthio, 2-benzoxazolylthio, 2-benzothiazolylthio or the like), or a siloxy ligand (having preferably from 1 to 30, more preferably from 3 to 25, particularly preferably from 6 to 20 carbon atoms, such as triphenylsiloxy group, triethoxysiloxy group, triisopropylsiloxy group or the like) can be cited, of which a nitrogen-containing heterocyclic ligand, an aryloxy ligand, a heteroaryloxy ligand or a siloxy ligand is more preferred, and a nitrogen-containing heterocyclic ligand, an aryloxy ligand or a siloxy ligand is further preferred.

Preferred as the construction of the photoelectric conversion layer is a case in which it has a p-type semiconductor layer and an n-type semiconductor layer, wherein at least either one of said p-type semiconductor and n-type semiconductor is an organic semiconductor, and it contains a photoelectric conversion film (photosensitive layer) having a bulk heterojunction structure layer containing said p-type semiconductor and n-type semiconductor, as an intermediate layer between these semi conductor layers. In such a case, by containing the bulk heterojunction structure layer in the organic layer of the photoelectric conversion film, a disadvantage of short carrier diffusion length of the organic layer can be offset and the photoelectric conversion efficiency can be improved. In this connection, the bulk heterojunction structure is described in detail in Japanese Patent Application No. 2004-080639.

In addition, also preferred as the construction of the photoelectric conversion layer is such a case that a photoelectric conversion film (photosensitive layer) having a structure in which two or more of a repeating structure (tandem structure) of a pn junction layer formed from a p-type semiconductor layer and an n-type semiconductor layer is contained between a pair of electrodes, and further preferred is a case in which a thin film of a conductive material is inserted between the aforementioned repeating structures. The number of repeating structure (tandem structure) of pn junction layer may be any numbers, but in order to improve the photoelectric conversion efficiency, it is preferably from 2 to 50, more preferably from 2 to 30, and particularly preferably 2 or 10. As the conductive material, silver or gold is desirable, and silver is most desirable. In this connection, the tandem structure is described in detail in Japanese Patent Application No. 2004-079930.

It is desirable that film thickness of the organic pigment layer is as thick as possible from the viewpoint of light absorption, but when the ratio of not contributing to charge separation is taken into consideration, film thickness of the organic pigment layer of the invention is preferably 30 nm or more and 300 nm or less, more preferably 50 nm or more and 250 nm or less, particularly preferably 80 nm or more and 200 nm or less.

Regarding the method for forming these organic layers, a dry film forming method or a wet film forming method can be used. As illustrative examples of the dry film forming method, a vacuum deposition method, a spattering method, an ion plating method, an MBE method or the like physical vapor phase epitaxy method or a plasma polymerization or the like CVD method can be cited. As the wet film forming method, a cast method, a spin coat method, a dipping method, an LB method or the like coating method can be used. In addition, an ink jet printing, screen printing or the like printing method or a thermal transfer, laser transfer or the like transferring method may also be used. Patterning may be carried out by a chemical etching by photolithography or the like means, by a physical etching by an ultraviolet ray, laser or the like means, by a vacuum deposition, spattering or the like means after overlaying a mask, or by a lift off method, a printing method or a transferring method.

A case in which voltage is applied to a photoelectric conversion film is desirable because the photoelectric conversion efficiency is improved. The applying voltage may be any voltage, but the necessary voltage is changed depending on the film thickness of the photoelectric conversion film. That is, the photoelectric conversion efficiency is improved as the electric field added to the photoelectric conversion film becomes large, but even at the same applying voltage, the added electric field becomes large as film thickness of the photoelectric conversion film becomes thin. Accordingly, when film thickness of the photoelectric conversion film is thin, the applying voltage may be relatively small. Preferred as the electric field to be added to the photoelectric conversion film is preferably 1.0×10⁵ V/m or more. An electric current flows when too large electric field is added even in the dark, which is not desirable, so that 1×10⁷ V/m or less is desirable.

### (Laminate Type Photoelectric Conversion Element)

The layer of the organic photoelectric conversion element of the invention can be made into a laminate type photoelectric conversion element by laminating it with other photoelectric conversion element layer.

The following describes the laminate type photoelectric conversion element.

The photoelectric conversion element consists of an electromagnetic wave absorption/photoelectric conversion part and a charge accumulation/transfer/readout part of the charge formed by the photoelectric conversion.

The electromagnetic wave absorption/photoelectric conversion part has at least two layers of a laminate type structure which can absorb at least blue light, green light and red light and effect their photoelectric conversion. The blue absorption layer (B) can absorb at least a light of from 400 to 500 nm, and absorption ratio of the peak wave length within the wavelength range is preferably 50% or more. The green absorption layer (G) can absorb at least a light of from 500 to 600 nm, and absorption ratio of the peak wave length within the wavelength range is preferably 50% or more. The red absorption layer (R) can absorb at least a light of from 600 to 700 nm, and absorption ratio of the peak wave length within the wavelength range is preferably 50% or more. The order of these layers may be any order, and in the case of a three layer laminate type structure, an order of BGR, BRG, GBR, GRB, RBG and RGB, starting from the upper layer, is possible. The uppermost layer is preferably G. In the case of a two layer laminate type structure, BG layer is formed on the lower layer in a coplanar form when the upper layer is R layer, and GR layer on the lower layer in a coplanar form when the upper layer is B layer, and BR layer on the lower layer in a coplanar form when the upper layer is G layer. Preferably, the upper layer is G layer and the lower layer BR layer in a coplanar form. When two light absorbing layers are arranged on the lower layer in a coplanar form like this case, it is desirable to arrange a filter layer which can fractionate colors on the upside of the upper layer or between the upper layer and lower layer, for example in a mosaic shape. As occasion demands, it is possible to arrange a fourth layer or more as a new layer or in a coplanar form.

The charge accumulation/transfer/readout part is arranged on the lower side of the electromagnetic wave absorption/photoelectric conversion part. It is desirable that the electromagnetic wave absorption/photoelectric conversion part of the lower layer serves as the charge accumulation/transfer/readout part.

The electromagnetic wave absorption/photoelectric conversion part consists of an inorganic layer or a mixture of an organic layer and an inorganic layer. The organic layer may form a B/G/R layer or the inorganic layer may form a B/G/R layer. Preferred is a mixture of an organic layer and an inorganic layer. In that case, the inorganic layer is basically single layer or double layer when the organic layer is single layer, and the inorganic layer is single when the organic layer is double layer. When the organic layer and inorganic layer are single layer, the inorganic layer forms an electromagnetic wave absorption/photoelectric conversion part of two or more colors in a coplanar form. Preferably, the upper layer is an organic layer and G layer, and the lower layer is an inorganic layer and an order of B layer and R layer counting from the upper side. As occasion demands, it is possible to arrange a fourth layer or more as a new layer or in a coplanar form. When the organic layer forms a B/G/R layer, the charge accumulation/transfer/readout part is arranged on the lower side. When an inorganic layer is used as the electromagnetic wave absorption/photoelectric conversion part, this inorganic layer serves as a charge accumulation/transfer/readout part

### (Inorganic Layer)

The inorganic layer as the electromagnetic wave absorption/photoelectric conversion part is described. In this case, photoelectric conversion of the light passed through the upper layer organic layer is effected in the inorganic layer. As the inorganic layer, a pn junction or pin junction of crystal silicon, amorphous silicon, GaAs and the like compound semiconductors is generally used. As a laminate type structure, the method disclosed in U.S. Pat. No. 5,965,875 can be employed. That is, this is a construction in which a light receiving part laminated making use of the wavelength dependency of the absorption coefficient of silicon is formed, and separation of colors is carried out in its depth direction. In this case, since separation of colors is carried out by the light approaching depth of silicon, the spectral range to be detected by each of the laminated light receiving parts becomes broad. However, separation of colors is markedly improved by the use of the aforementioned organic layer in the upper layer, namely by detecting the light passed through the organic layer in the depth direction of silicon. Particularly, separation of colors is improved when G layer is arranged in the organic layer, because the lights passed through the organic layer become B light and R light so that selection of lights in the depth direction of silicon becomes only of the BR lights. Even when the organic layer is B layer or R layer, separation of colors is markedly improved by optionally selecting the electromagnetic wave absorption/photoelectric conversion part in the depth direction of silicon. When the organic layer is a double layer, function of the electromagnetic wave absorption/photoelectric conversion part can be basically one color so that a desirable color separation can be attained.

Preferably, the inorganic layer has a structure in which two or more photodiodes are overlaid for each picture element in the depth direction in the semiconductor substrate, and a color signal corresponding to the signal charge formed in each photodiode is readout into an outside part, based on the lights absorbed by the aforementioned two or more photodiodes. Preferably, it is desirable that the aforementioned two or more photodiodes contain at least one of a first photodiode arranged at a depth where the B light is absorbed and a second photodiode arranged at a depth where the R light is absorbed, and are equipped with a color signal readout circuit which readouts a color signal in response to the aforementioned signal charge formed in each of the aforementioned two or more photodiodes. By this construction, color separation can be carried out without using a color filter. Also, since a light of negative sensitivity component can be detected in some cases, a color image-taking having excellent color reproducibility becomes possible. In addition, it is desirable that the junction part of the aforementioned first photodiode is formed at a depth of about 0.2 μm from the surface of the aforementioned semiconductor substrate, and the junction part of the aforementioned second photodiode is formed at a depth of about 2 μm from the surface of the aforementioned semiconductor substrate.

The inorganic layer is described further in detail. As preferred construction of the inorganic layer, photoconductive type, p-n junction type, Shottky junction type, PIN junction type and MSM (metal-semiconductor-metal) type light-receiving elements and phototransistor type light-receiving element can be exemplified. It is desirable to use a light-receiving element in which two or more of a first conductive type region and a second conductive type region as a reverse conductive type of the aforementioned first conductive type are alternatively laminated in a single semiconductor substrate, and respective junction faces of the aforementioned first conductive type and second conductive type regions are formed at certain depths suited for mainly effecting photoelectric conversion of lights of respectively different two or more wavelength areas. A single crystal silicon is desirable as the single semiconductor substrate, and the color separation can be carried out making use of the absorption wavelength characteristics which depend on the depth direction of the silicon substrate.

As the inorganic semiconductor, an inorganic semiconductor of InGaN system, InAlN system, InAlP system or InGaAlP system can also be used. The inorganic semiconductor of InGaN system is prepared by optionally changing containing composition of In such a manner that it has a maximum absorption value within the wavelength range of blue color. That is, it becomes a composition of InₓGa₁₋ₓN (0≦x<1). Such a compound semiconductor is produced using an organic metal vapor phase epitaxy method (MOCVD method). The InAlN system of nitride semiconductor which uses Al as the same group 13 material of Ga can also be used a shorter wavelength light receiving part similar to the case of the InGaN system. In addition, the InAlP or InGaAlP which lattice-interfaces with GaAs substrate can also be used.

The inorganic semiconductor may form an imbedding structure. The imbedding structure is a construction in which both termini of the shorter wavelength light receiving part are covered with a semiconductor which is different from the shorter wavelength light receiving part. It is desirable that the semiconductor which covers both termini is a semiconductor which has a band gap wavelength shorter than or equal to the band gap wavelength of the shorter wavelength light receiving part.

The organic layer and inorganic layer may be connected by any form.

In addition, it is desirable to arrange an insulation layer between the organic layer and inorganic layer to effect their electric insulation.

It is desirable that the junction is npn or pnpn starting from the light incidence side. Particularly, it is most desirable to effect the pnpn junction, because when the surface electric potential is increased through the arrangement of p layer on the surface, the positive hole generated around the surface and the dark current can be trapped and the dark current can be reduced.

In such a photodiode, the pn junction diode is formed in 4 layers of pnpn in the depth direction of silicon, by deeply forming n type layer, p type layer, n type layer and p type layer in that order which are diffused in order from the p type silicon substrate surface. Since the light incoming into the diode from its surface side deeply penetrates as the wavelength is long, and the incident wavelength and attenuation coefficient show silicon-specific values, this is designed in such a manner that depth of the pn junction face covers respective wavelength ranges of visible light. In the same manner, a junction diode of 3 layers of npn is obtained by forming them in order of n type layer, p type layer and n type layer. In this case, a light signal is taken out from the n type layer, and the p type layer is connected to a ground earth.

In addition, when a leading electrode is arranged in each range and a predetermined reset potential is applied, each range becomes a depleted state and the capacity of each junction part becomes limitlessly small. By this, the capacity forming on the junction face can be extremely lessened.

### (Auxiliary Layers)

Preferably, an ultraviolet ray absorption layer and/or an infrared absorption layer is arranged on the uppermost layer of the electromagnetic wave absorption/photoelectric conversion part. The ultraviolet ray absorption layer can absorb or reflect a light of at least 400 nm or less, and the absorption ratio in the wavelength range of 400 nm or less is preferably 50% or more. The infrared absorption layer can absorb or reflect a light of at least 700 nm or less, and the absorption ratio in the wavelength range of 700 nm or less is preferably 50% or more.

These ultraviolet ray absorption layer and infrared absorption layer can be formed by a conventionally known method. For example, a method is known in which a mordanting layer consisting of gelatin, casein, glue, polyvinyl alcohol or the like hydrophilic high molecular substance is arranged on a substrate, and a pigment having a desired absorption wavelength is added to the mordanting layer or the layer is stained therewith to form a coloring layer. In addition, a method is known which uses a coloring resin in which a certain kind of coloring material is dispersed in a transparent resin. For example, as shown in JP-A-58-46325, JP-A-60-78401, JP-A-60-184202, JP-A-60-184203, JP-A-60-184204, JP-A-60-184205 and the like, a coloring resin film prepared by mixing a polyamino system resin with a coloring material can be used. a coloring agent which uses a polyimide resin having photosensitivity can also be applicable.

Dispersion of a coloring material in the aromatic polyamide resin described in JP-B-7-113685, which is possessed of a group having photosensitivity in the molecule and from which a hardened film can be obtained at 200° C. or less, and use of a coloring resin in which the pigment described in JP-B-7-69486 is dispersed can also be applicable.

A dielectric multilayer film is suitably used. The dielectric multilayer film is suitably used because of the sharp wavelength dependency of light permeation.

It is desirable that each electromagnetic wave absorption/photoelectric conversion part is separated by an insulation layer. The insulation layer can be formed using a transparent insulation material such as glass, polyethylene, polyethylene terephthalate, polyether sulfone, polypropylene or the like. Silicon nitride, silicon oxide and the like are also used preferably. Silicon nitride made into a film by plasma CVD is desirably used because of its high compactness and good transparency.

A protecting layer or sealing layer can also be arranged for the purpose of preventing contact with oxygen, moisture and the like. As the protecting layer, a diamond thin film, an inorganic material film such as of a metal oxide or a metal nitride, a polymer film such as of fluoride resin, poly-p-xylene, polyethylene, silicon resin or polystyrene resin, and a photo-curable resin can be exemplified. In addition, it is possible also to cover the element part with glass, a gas-impermeable plastic material, a metal or the like, and to effect packaging of the element itself with an appropriate sealing resin. In this case, it is possible also to allow a substance having high water absorbability to present in side the packaging.

In addition, since condensing efficiency can be improved by forming micro-lens array on the upper part of the light receiving element, such an embodiment is also desirable.

### (Charge Accumulation/Transfer/Readout Part)

Regarding the charge transfer/readout part, JP-A-58-103166, JP-A-58-103165, JP-A-2003-332551 and the like can be used as references. A construction in which MOS transistor is formed in each picture element unit on a semiconductor substrate or a construction which has CCD as an element can be optionally employed. For example, in the case of a photoelectric conversion element which uses MOS transistor, a charge is generated in the photoconductive film by the incident light permeated through the electrode, the charge is transferred in the photoconductive film toward an electrode by the electric field generated between electrodes when voltage is applied to an electrode, and the charge is transferred to the charge accumulation part of MOS transistor and accumulated in the charge accumulation part. The charge accumulated in the charge accumulation part is transferred to the charge readout part by the switching of MOS transistor and further output as an electric signal. By this, a full color image signal input in the solid image-taking device containing a signal treating part.

It is possible to inject a predetermined amount of bias charge into an accumulation diode (refresh mode) and thereby to effect readout of the signal charge after accumulation of a predetermined amount of charge (photoelectric conversion). The light receiving element itself can be used as the accumulation diode, or a special accumulation diode can be arranged.

Readout of signals is described further in detail. Usual color readout circuit can be used in the readout of signals. The signal charge or signal current photo/electric transferred at the light receiving part is accumulated in the light receiving part itself or an annexed capacitor. The accumulated charge is readout together with the selection of picture element position by means of an X-Y address-aided MOS type image-taking element (so-called CMOS sensor). In another address selection system, picture elements are selected one by one in succession by a multiplex switch and a digital shift resister and readout as a signal voltage (or charge) on a common output line. The image-taking element of two-dimensionally arrayed X-Y address operation is known as CMOS sensor. In this system, a switch arranged in a picture element connected to the X-Y intersection is connected to a vertical shift register, and when the switch is turned on by the voltage from the vertical scanning shift register, the signal readout from a picture element arranged on the same line is readout by a column direction output line. This signal is readout in order from the output terminal through a switch which is driven by a horizontal scanning shift register.

A floating diffusion detector or a floating gate detector can be used for the readout of output signals. In addition, improvement of S/N can be achieved by arranging a signal amplification circuit in the picture element part or by a technique of correlated double sampling.

A gamma correction by ADC circuit, a digital treatment by AD converter, a luminance signal treatment or a color signal treatment can be applied to the signal treatment. As the color signal treatment, a white balance treatment, a color separation treatment, a color matrix treatment and the like can be exemplified. When used in NTSC signal, RGB signal can be subjected to a conversion treatment of YIQ signal.

It is necessary that the charge transfer/readout part has a charge mobility of 100 cm²·V⁻¹·s⁻¹ or more, and this mobility can be obtained by selecting the material from semiconductors of the group IV, group III-V and group II-VI. Among them, a silicon semiconductor is desirable because of the progress of refining techniques and low cost. Many charge transfer/charge readout systems have been proposed, but any system may be used. Particularly desirable system is a CMOS type or CCD type device. The CMOS type has much more desirable points in terms of high speed readout, picture element summing, partial readout, consuming electric power and the like.

### (Connection)

Regarding the two or more of contact parts which connect the electromagnetic wave absorption/photoelectric conversion parts to the charge transfer/readout parts, they may be connected with any metal, but it is desirable to select it from copper, aluminum, silver, gold, chromium and tungsten, of which cupper is particularly desirable. It is necessary to arrange respective contact parts between the charge transfer/readout parts, in response to two or more of the electromagnetic wave absorption/photoelectric conversion parts. When a laminate structure of two or more photosensitive units of blue, green and red lights is desired, it is necessary to connect the electrode for blue light take out with the charge transfer/readout part, and the electrode for red light take out with the charge transfer/readout part, respectively.

### (Process)

The laminated photoelectric conversion element can be produced in accordance with the so-called micro-fabrication process which is used in the conventionally known production of integrated circuits and the like. Basically, this method is based on the repetitive operation of pattern exposure by active light, electron beam or the like (i or g bright line of mercury, excimer laser, or X ray, electron beam), pattern formation by development and/or burning, arrangement of element forming material (coating, vapor deposition, sputter, CV or the like) and removal of material of non-pattern parts (heat treatment, dissolution treatment or the like).

### (Application)

Regarding chip size of the device, it can be selected from brownie size, 135 size, APS size, 1/1.8 inch size and a size of further small type. Picture element size of the laminate type photoelectric conversion element is expressed by a circle-equivalent diameter which is equivalent to the maximum area of two or more electromagnetic wave absorption/photoelectric conversion parts. It may be any picture element size, but a picture element size of from 2 to 20 microns is preferable. More preferred is from 2 to 10 microns, and from 3 to 8 microns is particularly preferable.

Resolving power is reduced when the picture element size exceeds 20 microns, and the resolving power is also reduced even when the picture element size is smaller than 2 microns due, probably, to the electric wave interference between sizes.

The laminate type photoelectric conversion element can be used in a digital still camera. In addition, its use in a TV camera is also preferable. As other applications, it can be used in such applications as a digital video camera, a monitor camera for the following uses (an office building, a parking lot, a financial organ, a self-service contracting machine, a shopping center, a convenience store, an outlet mall, a department store, a pachinko hall, a do-it-yourself vocal box, a game center, a hospital), picture-taking elements including a facsimile, a scanner and a copier, other various sensors (a TV door phone, a sensor for individual identification, a sensor for factory automation, a domestic robot, an industrial robot, a piping inspection system), medical sensors (an endoscope, a fundus camera), a TV conference system, a TV phone, a pocket telephone equipped with camera, motor car safe driving systems (a back guide monitor, a collision prediction, a lane keeping system), a sensor for TV game and the like.

Among these, the laminate type photoelectric conversion element is suited for TV camera use. The reason for this is that miniaturization and lightening of TV camera can be attained because a color separation optical system is not necessary. In addition, since it has high resolving power with high sensitivity, this element is particularly suitable for a TV camera for high vision broadcasting. The TV camera for high vision broadcasting in this case includes a camera for digital high vision broadcasting.

In addition, the laminate type photoelectric conversion element is desirable from the viewpoint that further high sensitivity and high resolving power can be expected because an optical low-pass filter can be avoid.

What is more, since it is possible to thin its thickness and a color separation optical system becomes unnecessary in the case of the laminate type photoelectric conversion element, this can meet various photographing needs with one camera by carrying out the photographing while changing the photoelectric conversion element of the invention, for photographing scenes which require different sensitivities such as “environments of different lightness such as the daytime and the night time”, “a standing camera subject and a moving camera subject” and the like and other photograph ing scenes which have different requirements for spectral sensitivity and color reproducibility, and at the same time, burden to a photographer is also alleviated because it is not necessary to carry two or more cameras. As the photoelectric conversion elements to be changed, exchanging photoelectric conversion elements can be prepared for the purpose of changing dynamic ranges, for infrared photographing and black-and-white photographing in addition to the aforementioned cases.

A TV camera can be prepared with reference to the description of chapter 2 of “Designing Techniques of Television Camera” edited by the Image Information Media Society (written in Japanese, published by Colona in 1999), for example by replacing the part of FIG. 2.1 “Color separation optical system and image-taking device of basic constitution of television camera” with the laminate type photoelectric conversion element.

The aforementioned laminated light receiving elements can be used as image-taking elements by ordering them and also can be used, as a single body, as a biosensor, chemical sensor or the like light sensor or a color light receiving element.

### EXAMPLES

### Example 1

### FIG. 10

A 25 mm square glass substrate equipped with ITO (Wf: 4.8 eV) was subjected to ultrasonic cleaning with acetone, Semico Clean and isopropyl alcohol (IPA), each for 15 minutes. After finally washing with boiling IPA, UV/O₃ washing was carried out.

This substrate was transferred into an organic vapor deposition chamber, and pressure in the chamber was reduced to 1×10⁻⁴ Pa or less. Thereafter, PR-122 (mfd. by DOJINDO) (Ea: 3.2 eV, Ip: 5.2 eV) purified 3 times or more by sublimation was deposited thereon at a deposition rate of from 0.5 to 1 Å/sec and to a thickness of 1000 Å by a resistance heating method while rotating the substrate holder. Subsequently, a compound HB-1 (Ea: 3.5 eV, Ip: 6.2 eV) purified by sublimation was deposited thereon at a deposition rate of from 1 to 2 Å/sec and to a thickness of 500 Å.

Next, the substrate deposited with the organic materials were transferred into a metal deposition chamber whole keeping in-vacuum. Thereafter, Al (Wf: 4.3 eV) was deposited as a counter electrode to a thickness of 800 Åwhile keeping the chamber under 1×10⁻⁴ Pa or less. Also, the area of the photoelectric conversion region formed by ITO to be used as the picture element electrode and Al to be used as the counter electrode was set to 2 mm×2 mm.

This substrate was transferred, without exposing to the air, into a glove box where moisture and oxygen were respectively kept at 1 ppm or less, and its sealing with a sealing can to which a moisture absorbent had been applied was carried out using a UV curable resin.

PR-122 (Photoelectric Conversion Material)

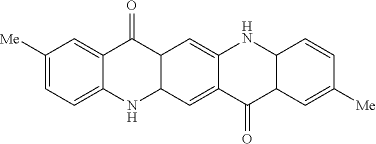 [SMILES: CC1=CC2C(=O)C3=CC4Nc5ccc(C)cc5C(=O)C4C=C3NC2C=C1]

HB-1 (Positive Hole Blocking Material)

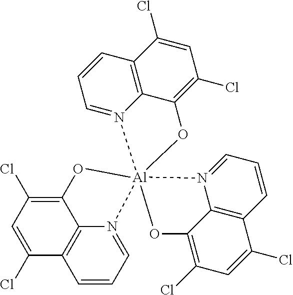

A value of dark current flowing at the time of no light irradiation and a value of light current flowing at the time of light irradiation, when an external electric field of 1.0×10⁶ V/cm was added to this element, were measured using an energy quantum efficiency measuring apparatus manufactured by Optel (Cathley 6430 was used as the source meter), and external quantum efficiency (IPCE) at a wavelength of 550 nm was calculated from these values. Regarding the IPCE, the quantum efficiency was calculated using a signal current value obtained by subtracting the dark current value from the light current value. The irradiated quantity of light was set to 50 μW/cm².

### Example 2

### FIG. 11

Firstly, EB-1 (Ea: 1.9 eV, Ip: 4.9 eV) purified by sublimation was deposited on a substrate equipped with ITO, which had been washed in the sama manner as in Example 1, at a deposition rate of from 1 to 2 Å/sec and to a thickness of 500 Åunder the same conditions of Example 1. Subsequently, PR-122 (mfd. by DOJINDO) purified 3 times or more by sublimation was deposited thereon at a deposition rate of from 0.5 to 1 Å/sec and to a thickness of 1000 Å.

Next, in the same manner as in Example 1, this substrate was transferred into a metal deposition chamber to carry out deposition of Al and further sealed, and then measurement of light current, dark current and IPCE was carried out.

EB-1 (Electron Blocking Material)

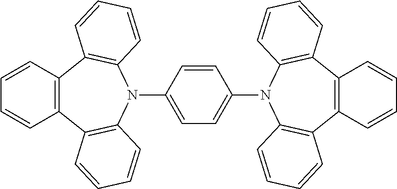 [SMILES: c1ccc2c(c1)-c1ccccc1N(c1ccc(N3c4ccccc4-c4ccccc4-c4ccccc43)cc1)c1ccccc1-2]

### Example 3

### FIG. 12

In the same manner as in Example 2, films of EB-1 and PR-122 were formed on a washed substrate equipped with ITO, and then HB-1 was deposited thereon at a deposition rate of from 1 to 2 Å/sec and to a thickness of 500 Å.

Next, in the same manner as in Example 1, this substrate was transferred into a metal deposition chamber to carry out deposition of Al and further sealed, and then measurement of light current, dark current and IPCE was carried out.

### Example 4

The procedure of Example 1 was repeated, except that 1% of BEDT-TTF (mfd. by Tokyo Kasei, sublimation-purified) was simultaneously co-deposited when HB-1 was deposited.

### BEDT-TTF (Doping Material to Positive Hole Blocking Layer)

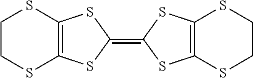 [SMILES: C1CSC2=C(S1)SC(=C1SC3=C(SCCS3)S1)S2]

### Example 5

The procedure of Example 2 was repeated, except that 1% of F4TCNQ (mfd. by Tokyo Kasei, sublimation-purified) was simultaneously co-deposited when EB-1 was deposited.

F4TCNQ (Doping Material to Electron Blocking Layer)

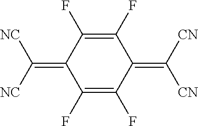 [SMILES: N#CC(C#N)=c1c(F)c(F)c(=C(C#N)C#N)c(F)c1F]

### Comparative Example 1

### FIG. 13

A film of PR-122 was formed under the same conditions as in Example 1 on a substrate equipped with ITO which had been washed in the same manner as in Example 1, this substrate was subsequently transferred into a metal deposition chamber to carry out deposition of Al and further sealed, and then measurement of light current, dark current and IPCE was carried out.

### Comparative Example 2

### FIG. 14

Preparation of an element and evaluation of its performance were carried out under the same conditions of Example 1, except that Alq3 (mfd. by NIPPON STEEL CORP, sublimation-purified) (Ea: 3.0 eV, Ip: 5.8 eV) was used instead of HB-1.

Alq3 (Positive Hole Blocking Material)

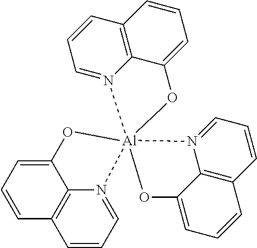

### Comparative Example 3

### FIG. 15

Preparation of an element and evaluation of its performance were carried out under the same conditions of Example 1, except that HB-10 (mfd. by Aldrich, sublimation-purified) (Ea: 3.3 eV, Ip: 5.3 eV) was used instead of HB-1.

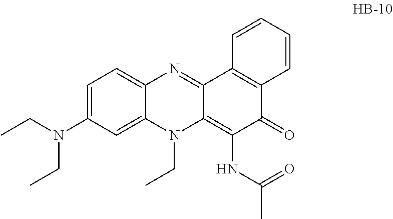 [SMILES: CCN(CC)c1ccc2nc3c4ccccc4c(=O)c(NC(C)=O)c-3n(CC)c2c1]

### Comparative Example 4

### FIG. 16

Preparation of an element and evaluation of its performance were carried out under the same conditions of Example 1, except that EB-10 (sublimation-purified) (Ea: 1.9 eV, Ip: 4.9 eV) was used instead of EB-1.

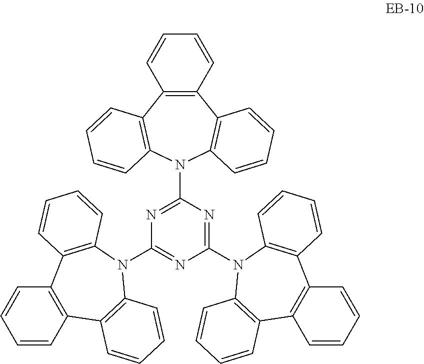 [SMILES: c1ccc2c(c1)-c1ccccc1N(c1nc(N3c4ccccc4-c4ccccc4-c4ccccc43)nc(N3c4ccccc4-c4ccccc4-c4ccccc43)n1)c1ccccc1-2]

Dark current values and IPCE values are shown in Table 1.

TABLE 1

| | | Electron | | | | Dark | |
|---|---|---|---|---|---|---|---|
| | | blocking | Photoelectric | Positive hole | | current | |
| Example | Electrode | layer | conversion layer | blocking layer | Electrode | (*) | IPCE |
| Ex. 1 | ITO | none | PR-122 | HB-1 | Al | 9.1 × 10⁻¹⁰ | 35% |
| Ex. 2 | ITO | EB-1 | PR-122 | none | Al | 7.2 × 10⁻⁸ | 38% |
| Ex. 3 | ITO | EB-1 | PR-122 | HB-1 | Al | 1.1 × 10⁻¹⁰ | 39% |
| Ex. 4 | ITO | none | PR-122 | HB-1 + | Al | 6.4 × 10⁻¹⁰ | 33% |
| | | | | BEDT- | | | |
| | | | | TTF (1%) | | | |
| Ex. 5 | ITO | EB-1 + | PR-122 | none | Al | 2.1 × 10⁻⁸ | 35% |
| | | F4TCNQ (1%) | | | | | |
| Comp. 1 | ITO | none | PR-122 | none | Al | 2.4 × 10⁻⁶ | 33% |
| Comp. 2 | ITO | none | PR-122 | Alq3 | Al | 1.5 × 10⁻⁹ | 28% |
| Comp. 3 | ITO | none | PR-122 | HB-10 | Al | 9.5 × 10⁻⁷ | 33% |
| Comp. 4 | ITO | EB-10 | PR-122 | none | Al | 7.1 × 10⁻⁸ | 25% |

(*) A/cm²
Ex. means Example, and
Comp. means Comparative Example. [Results]

### [Result]

In comparison with Comparative Example 1 in which a blocking layer was not arranged, dark current was reduced by a factor of 3 digits or more in Example 1 in which a positive hole blocking layer was arranged, and a dark current reduction by a factor of close to 2 digits was also found in Example 2 in which an electron blocking layer was arranged. In this case, reduction of IPCE was not found, but it increased slightly rather on the contrary. It was considered that this may be due to the contribution of charge separation caused by the bending of band at boundary face effected by the internal electric field of PR-122 and the blocking layer.

In addition, in Example 3 in which both of the positive hole blocking layer and electron blocking layer were arranged, it was able to reduce dark current by a factor of 4 digits or more in comparison with Comparative Example 1, and improvement of IPCE was also found.

In the case of Comparative Example 2 in which Alq3 (Ea: 3.0 eV, Ip: 5.8 eV) having an Ea value of smaller than PR-122 (Ea: 3.2 eV, Ip: 5.2 eV) was used as the positive hole blocking layer, the blocking ability was high and the value of dark current was close to that of Example 1, but readout efficiency of the generated carrier was reduced and IPCE was sharply reduced due to the presence of energy barrier of Ea.

In addition, in the case of Comparative Example 3 in which HB-10 (Ea: 3.3 eV, Ip: 5.3 eV) having a small Ip value was used as the positive hole blocking layer, its blocking ability is not sufficient because of the small difference between the work function of Al (Wf: 4.3 eV) adjacent to HB-10 and the Ip of HB-10, so that dark current was hardly reduced in comparison with Comparative Example 1 and it did not complete its function as the blocking layer.

Also in the case of the electron blocking layer, IPCE was sharply reduced when EB-10 (Ea: 1.9 eV, Ip: 4.9 eV), in which Ip is larger than PR-122 (Ea: 3.2 eV, Ip: 5.2 eV) and energy barrier of Ip is present at the time of the carrier readout, was used like the case of Comparative Example 4.

In the case of Example 4 in which BEDT-TTF having strong electron donative property was doped to the positive hole blocking layer, dark current was reduced in comparison with Example 1. The reason why dark current is reduced by BEDT-TTF is not completely understood, but it is considered that this is due to the reduction of positive hole injection from electrode because of the presence of the electron donative BEDT-TTF.

In addition, in the case of Example 5 in which F4TCNQ having strong electron acceptable property was doped to the electron blocking layer, dark current was reduced in comparison with Example 2. The reason why dark current is reduced by F4TCNQ is not completely understood, but it is considered that this is due to the reduction of electron injection from electrode because of the presence of the electron acceptable F4TCNQ.

Based on the above, it was able to reduce dark current and increase IPCE and to sharply improve S/N ratio, by properly selecting relationship of Ea of the photoelectric conversion layer and Ea of the positive hole blocking layer, Ip of the photoelectric conversion layer and Ip of the electron blocking layer and Ip of the positive hole blocking layer and Ea of the electron blocking layer to the work function Wf of the respectively adjoining electrodes.

In addition, it was able to further reduce dark current by the doping to the blocking layer.

Since the organic photoelectric conversion element of the invention can effectively prevent positive hole injection or electron injection from the electrodes, and it has an organic blocking layer which does not prevent passage of the carrier generated by light irradiation, it becomes possible to provide an organic photoelectric conversion element in which dark current is not increased and photoelectric conversion efficiency is not reduced even when voltage is applied from the outside.

The entire disclosure of each and every foreign patent application from which the benefit of foreign priority has been claimed in the present application is incorporated herein by reference, as if fully set forth.

What is claimed is:

1. An organic photoelectric conversion element comprising:
a pair of electrodes;
an organic photoelectric conversion layer arranged between the pair of electrodes; and
an organic positive hole blocking layer arranged between one of the pair of electrodes and the organic photoelectric conversion layer,
wherein an ionization potential of the organic positive hole blocking layer is larger than a work function of the adjoining one of the pair of electrodes by 1.3 eV or more,
an electron affinity of the organic positive hole blocking layer is equal to or larger than an electron affinity of the adjoining organic photoelectric conversion layer, and
the organic electric conversion layer includes an organic compound purified by sublimation.

2. An organic photoelectric conversion element comprising:
a pair of electrodes;
an organic photoelectric conversion layer arranged between the pair of electrodes; and
an organic electron blocking layer arranged between one of the pair of electrodes and the organic photoelectric conversion layer,
wherein an electron affinity of the organic electron blocking layer is smaller than a work function of the adjoining one of the pair of electrodes by 1.3 eV or more,
an ionization potential of the organic electron blocking layer is equal to or smaller than an ionization potential of the adjoining organic photoelectric conversion layer, and
the organic electric conversion layer includes an organic compound purified by sublimation.

3. An organic photoelectric conversion element comprising:
a pair of electrodes;
an organic photoelectric conversion layer arranged between the pair of electrodes;
an organic positive hole blocking layer arranged between one of the pair of electrodes and the organic photoelectric conversion layer; and
an organic electron blocking layer arranged between the other one of the pair of electrodes and the organic photoelectric conversion layer,
wherein an ionization potential of the organic positive hole blocking layer is larger than a work function of the adjoining one of the pair of electrodes by 1.3 eV or more,
an electron affinity of the organic positive hole blocking layer is equal to or larger than an electron affinity of the adjoining organic photoelectric conversion layer,
an electron affinity of the organic electron blocking layer is smaller than a work function of the adjoining other one of the pair of electrodes by 1.3 eV or more,
an ionization potential of the organic electron blocking layer is equal to or smaller than an ionization potential of the adjoining organic photoelectric conversion layer, and
the organic electric conversion layer includes an organic compound purified by sublimation.

4. The organic photoelectric conversion element according to claim 1,
wherein an electron donative material is mixed in the organic positive hole blocking layer in an amount of from 0.1 wt % to 30 wt %.

5. The organic photoelectric conversion element to claim 2,
wherein an electron acceptable material is mixed in the organic electron blocking layer in an amount of from 0.1 wt % to 30 wt %.

6. The organic photoelectric conversion element according to claim 2,
wherein a thickness of the organic blocking layer is from 10 nm to 200 nm.

7. The organic photoelectric conversion element according to claim 2,
wherein a voltage to be applied from the outside is from 1.0×10⁵ V/cm to 1.0×10⁷ V/cm.

8. The organic photoelectric conversion element according to claim 1, wherein the organic compound is purified multiple times by sublimation.

9. The organic photoelectric conversion element according to claim 2, wherein the organic compound is purified multiple times by sublimation.

10. The organic photoelectric conversion element according to claim 3, wherein the organic compound is purified multiple times by sublimation.

11. The organic photoelectric conversion element according to claim 3, further comprising a readout circuit including a CCD or a CMOS.

12. An image element comprising an organic photoelectric conversion element according to claim 2.
